(19) United States
(12) Patent Application Publication
(10) Pub. No.: US 2008/0015269 A1
(43) Pub. Date: Jan. 17, 2008

(54) Hybrid polymer light-emitting devices

(76) Inventors: Guillermo C. Bazan, Goleta, CA (US); Renqiang Yang, Goleta, CA (US); Andres Garcia, Los Angeles, CA (US); Thuc-Quyen Nguyen, Goleta, CA (US); Hongbin Wu, Guangzhou (CN)

Correspondence Address: Robert Berliner;BERLINER & ASSOCIATES, 31st Floor, 555 W. Fifth Street, Los Angeles, CA, 90013, US

(21) Appl. No.: 11/729,074

(22) Filed: Mar. 27, 2007

Related U.S. Application Data
(60) Provisional application No. 60/792,881, filed on Apr. 17, 2006.

(51) Int. Cl. B01J 41/12; B41J 2/175; H01L 29/861

(52) U.S. Cl. 521/30; 205/703; 313/483; 347/86

(57) ABSTRACT

A salt is provided comprised of a polyionic conjugated polymer comprising a plurality of first charges; and a plurality of counterions, each of said plurality comprising a charged moiety electronically linked to at least one charge-distributing moiety, said charged moiety having a charge opposite in sign to that of the first charge. These polyionic conjugated polymers having different electronic and/or optical properties.

### CROSS-REFERENCE TO RELATED APPLICATIONS

This application claims the benefit of U.S. Provisional Application No. 60/792,881 filed on Apr. 17, 2006, which is incorporated herein by reference in its entirety.

### FIELD OF THE INVENTION

This invention relates to polyionic conjugated polymers with introduced/substituted counterions, compositions comprising such materials, methods of making and using them, and articles incorporating them.

### BACKGROUND OF THE INVENTION

Conjugated polyelectrolytes (CPs) are under study for a variety of applications. Cationic CPs with a copolymer structure, such as those containing fluorene repeat units, have attracted much attention. Because their charged nature can make them water-soluble, they can be used for the optical amplification of fluorescent biosensors. The presence of charge compensating anions allows the design of single-component light-emitting electrochemical cells (LECs), thereby circumventing the need to create multicomponent blends. Additionally, because of their solubility in highly polar solvents, it is possible to use them in combination with organic-soluble neutral conjugated polymers to fabricate multilayer light-emitting diodes (LEDs) by alternating spin coating techniques.

Of the few reported studies relating to exchange of ions in polyionic conjugated polymers, most work has involved studying the effect of varying cations associated with anionic conjugated polymers.

Cimrova et al. studied the effect of proton, sodium and tetradecyltrimethyl ammonium cations on sulfonated poly(p-phenylene) (PPP) and its electrical and electroluminescent properties in single layer device [1]. The LED devices studied exhibited efficiencies of only 0.5-0.8%. The authors observed an electroluminescent redshift which they correlated with the size of the cation. The different sized cations were also said to have different conductivities, with the larger immobile tetradecyltrimethyl ammonium cation resulting in a higher onset voltage than the more mobile protons and sodium ions. The counterion was not found to affect the photoluminescence spectrum. The authors attributed the broadening of the EL spectra to the formation of aggregates that could act as trapping sites and recombination centers.

Thunemann et al. studied a series of ammonium, sulfonium and pyridinium cations in association with the blue-emitting polymer poly(1,4-phenyleneethynylene carboxylate) in solid state structures [2]. The authors speculated that the observed effects were due to the polarizability of the ionic headgroups of the cation, and concluded that the EL and PL spectra shifted to higher wavelengths when the counterions become more polarizable, from ammonium to pyridinium to sulfonium. The counterions were also said to have an influence on the effective conjugation length of the polymeric backbone. A number of the cations were amphiphilic, with lengthy hydrocarbon substituents, and formed smectic-like phases in the solid state. Significantly, aggregates of the ion pairs were found to form in solution. The quantum efficiencies of the single-layer LEDs prepared were not reported.

Baur et al. studied water-soluble ionic derivatives of poly(p-phenylene) (PPP), producing multilayer devices containing alternating layers of anionic and cationic polymers [3]. A number of polycationic polymers were studied in combination with anionic sulfonated PPP, including poly(allylamine hydrochloride) (PAR), polyethyleneimine (PEI), poly(vinylpyridine) (PvPy) and the tetrahydrothiophenium precursor to poly(phenylenevinylene), as well as polycationic PPP. The highest external quantum efficiency seen was only 0.01% for one combination of anionic PPP with PEI in a 1000 Angstrom film. No detailed photoluminescence or electroluminescence information was provided.

Some work has been done with cationic polythiophene, as a preparative clean-up step after catalytic oxidation [4]. No effect of the counterion on electronic, electroluminescent or photoluminescent properties was reported.

### BRIEF SUMMARY OF THE INVENTION

The present invention overcomes the need in the art for polyionic conjugated polymers having different electronic and/or optical properties, for methods of making and using them, and for compositions, articles of manufacture and machines comprising such compounds.

A salt is provided comprised of a polyionic conjugated polymer comprising a plurality of first charges; and a plurality of counterions, each of said plurality comprising a charged moiety electronically linked to at least one charge-distributing moiety, said charged moiety having a charge opposite in sign to that of the first charge.

In one embodiment, the first charges of the salt are positive charges; in an alternative embodiment, the first charges are negative charges.

The charged moiety can be negatively charged boron, sulfate, sulfonate, phosphate, phosphonate, carboxylate, and nitrate. In yet another embodiment, the charge-distributing moiety is comprised of an optionally substituted aromatic ring.

In one construction, the charge-distributing moiety comprises an electron-donating group or an electron-withdrawing group, where the electron-withdrawing group can be halogen and a haloalkyl group.

In another construction, the counterions of the salt is comprised of aryl borates; alternatively, the plurality of counterions is comprised of at least 7 atoms over which the charge is distributed.

The salt can be Poly[(9,9-bis(6′-N,N,N-trimethylammonium)hexyl)fluorene-alt-4,7-(2,1,3-benzothiadiazole)]tetrafluoroborate (PFBT-BF₄), Poly[(9,9-bis(6′-N,N,N-trimethylammonium)hexyl)fluorene-alt-4,7-(2,1,3-benzothiadiazole)]hexafluorophosphate (PFBT-PF₆), Poly[(9,9-bis(6′-N,N,N-trimethylammonium)hexyl)fluorene-alt-4,7-(2,1,3-benzothiadiazole)]trifluoromethanesulfonate (PFBT-CF₃S0₃), Poly[(9,9-bis(6′-N,N,N-trimethylammonium)hexyl)fluorene-alt-4,7-(2,1,3-benzothiadiazole)]tetraphenylborate (PFBT-BPh₄), Poly[(9,9-bis(6′-N,N,N-trimethylammonium)hexyl)fluorene-alt-4,7-(2,1,3-benzothiadiazole)]tetrakis(1-imidazolyl)borate (PFBT-BIm₄), Poly[(9,9-bis(6′-N,N,N-trimethylammonium)hexyl)fluorene-alt-4,7-(2,1,3-benzothiadiazole)]tetrakis(2-thienyl)borate (PFBT-BTh₄), Poly[(9,9-bis(6′-N,N,N-trimethylammonium)hexyl)fluorene-alt-4,7-(2,1,3-benzothiadiazole)]tetrakis[3,5-bis(trifluoromethyl)phenyl]borate (PFBT-BAr^{F}₄), Poly[(9,9-bis(6′-N,N,N-trimethylammonium)hexyl)fluorene]trifluoromethanesulfonate (PF-CF₃S0₃), Poly[(9,9-bis(6′-N,N,N-trimethylammonium)hexyl)fluorene]tetrakis(1-imidazolyl)borate (PF-BIm₄), Poly[(9,9-bis(6′-N,N,N-trimethylammonium)hexyl)fluorene]tetrakis[3,5-bis(trifluoromethyl)phenyl]borate (PF-BAr^{F}₄), Poly[(9,9-bis(6′-N,N,N-trimethylammonium)hexyl)fluorene-alt-1,4-phenyl)]tetrakis(pentafluorophenyl)borate (PFB-BPh^{F}₄), or Poly[(9,9-bis(6′-N,N,N-trimethylammonium)hexyl)fluorene-alt-4,4-((N-4′-(6″-N,N,N-trimethylammonium)hexyl)phenyl)diphenylamine]trifluoromethanesulfonate (PFTPA-CF₃S0₃).

The conjugated polymer can be a copolymer; alternatively the conjugated polymer can be optionally substituted polyfluorene, optionally substituted poly(fluorene-alt-benzothiadiazole), and optionally substituted poly(fluorene phenylene), or optionally substituted poly(fluorene triphenylamine).

The counterions of the salt are effective to reduce aggregation of the polyionic polymer as measured by at least one of: blue-shift of photoluminescent emission under at least one set of conditions; spectral width is narrowed; increased photoluminescent efficiency; reduced apparent size; and viscosity.

In one construction, the salt is purified. In another construction, the salt is combined with a solvent to form a solution, where the solvent can be dimethylsulfoxide, dimethylformamide, or methanol. The solution can be used in an inkjet cartridge.

The salt can be used as a film, where the film has a thickness of less than 200 nm. Alternatively, the salt can be used as a substrate layer.

In one embodiment, a method of improving the uniformity of a deposited layer of the salt is provided comprised of stirring a methanolic solution comprising said salt for at least 4 hours prior to deposition.

In another embodiment, an article of manufacture comprised of the salt is provided, where the article can be an optical component, an electrical component, an optoelectronic device, a biosensor, a photodiode, a light-emitting diode (LED), an optoelectronic semiconductor chip, a semiconductor thin-film, a field-effect transistor (FET), a polymeric photoswitch, an optical interconnect, a transducer, a lasing material, a light-emitting electrochemical cell (LECs), a solar cell, a photovoltaic, or a liquid crystal.

The light emitting diode comprised of the salt can exhibit one or more properties selected from increased luminance, altered onset voltage, and altered charge mobility, as compared to an LED not comprising said counterion. Within the LED the counterions can increase the ability of the conjugated polymer to inject and/or transport electrons. Within the LED, the salt can block the electrical transport of holes. In one embodiment, a plurality LEDs can be used in a matrix. In another embodiment, the LED can be used in a display device.

In one construction, a use of ion exchange with a conjugated polyelectrolyte is provided for the production and characterization of a solar cell, photovoltaic, or field-effect transistor. Ion exchange can alter the charge mobility, charge collection, and/or open circuit voltage of the solar cell or photovoltaic. Moreover, ion exchange can alter the charge mobility or charge injection of the field-effect transistor.

### BRIEF DESCRIPTIONS OF THE DRAWINGS

For a more complete understanding of the present invention, reference is now made to the following descriptions taken in conjunction with the accompanying drawing, in which:

FIG. 1 shows a XPS spectra of polyelectrolyte PFBT-Br.

FIG. 2 shows a XPS spectra of polyelectrolyte PFBT-BF₄.

FIG. 3 shows a XPS spectra of polyelectrolyte PFBT-PF₆.

FIG. 4 shows a XPS spectra of polyelectrolyte PFBT-CF₃SO₃ and S2p amplification.

FIG. 5 shows a XPS spectra of polyelectrolyte PFBT-BPh₄.

FIG. 6 shows a XPS spectra of polyelectrolyte PFBT-BIm₄ and N1s amplification.

FIG. 7 shows a XPS spectra of polyelectrolyte PFBT-BTh₄.

FIG. 8 shows a XPS spectra of polyelectrolyte PFBT-BAr^{F}₄.

FIG. 9 shows a XPS spectra of polyelectrolyte PFB-BPh^{F}₄.

FIG. 10 shows an absorption and PL spectra.

FIG. 11 shows a schematic of C-AFM experimental setup.

FIG. 12 shows a current density versus bias curves for PFBT-Br and PFBT-BAr^{F}₄.

FIG. 13 shows a current density and luminance versus bias curves for devices.

FIG. 14 shows a luminous efficiency versus bias curve for the device configuration ITO/PEDOT/DMO-PPV/ETL/AL.

### DETAILED DESCRIPTION OF THE INVENTION

The present invention provides counterions to ionic conjugated polymers which alter electronic and/or optical properties. In some aspects, counterion replacement appears to disrupt the ability of conjugated polymers to form aggregates which can decrease the efficiency of devices incorporating them. Desirable salts can be obtained comprising CPs and exchanged counterions following the methods of the invention.

Conjugated polyelectrolytes (CPs) are polymers exemplified by a π-conjugated backbone and functional groups that ionize in high dielectric media thereby making the material soluble in water and polar organic solvents. CPs embody the properties of polyelectrolytes, which are modulated by complex long-range electrostatic interactions, with the useful optical and electronic functions of organic semiconductors, which are determined to a significant extent by chain conformations and interchain contacts. Optical and electronic properties in solution and in the solid state are therefore difficult to predict a priori from simple molecular structure considerations.

Despite their complex structure/property relationships, CPs have found applications in substantially different technologies. For example, cationic CPs with a copolymer structure containing fluorene and phenylene repeat units can used for the optical amplification of fluorescent biosensors. In this function the conjugated backbone plays a light harvesting role, while the charged groups orchestrate electrostatic interactions as a function of a given recognition event. The presence of charge compensating counterions allows fabrication of light-emitting electrochemical cells (LECs) where the CP provides for a single component material that incorporates electrochemical (including charge compensating ions) and emissive functions, thereby circumventing the need to design and stabilize multi component blends. Because of their solubility in polar solvents, it is possible to use CPs in combination with neutral, organic soluble, conjugated polymers to fabricate multilayer polymer light emitting diodes by alternating spin-coating techniques. In the last application, the CPs have been used as electron or hole transport materials, because their solid-state emission quantum yields are typically low and are not likely to function well as the emitting layer.

Device function parameters that depend on the interchain packing of conjugated polymers are influenced by the chain conformations in solution. Properties such as the molecular constitution of the backbone and side groups, concentration, and solvents are well known to control the chain conformation. Work on non-conjugated polyelectrolytes has demonstrated that the nature of the backbone counterions modulates properties such as macromolecule conformations, interchain repulsion, solubility, polyion dimensions and stability. Much less is known in the case of CPs and in particular on the modification of optoelectronic properties by ion control of chain dimensions and contacts in solution and in the solid state.

The inventors have provided ion exchange methods and characterization procedures and have used the resulting materials to examine how the molecular properties of different counteranions (CAs) affect the solid state photoluminescence (PL) quantum yields, the nanoscale charge transport properties, and the aggregation of the chains in solution. In some embodiments, a typical cationic CP framework, namely poly[(9,9-bis(6′-N,N,N-trimethylammonium)hexyl)fluorene-alt-4,7-(2,1,3-benzothiadiazole)] (PFBT-X, where X corresponds to the charge compensating anion), was employed to exemplify the invention.

The inventors have demonstrated that it is possible to significantly improve the optical and electronic properties of conjugated polyelectrolytes by control of the charge compensating counterions. In some embodiments, procedures are provided for exchanging charge-compensating ions in conjugated polyelectrolytes by progressive dilution of the original species and for determining the degree of ion exchange by using X-ray photoelectron spectroscopy are provided. In some embodiments, the bromide ions in poly[(9,9-bis(6′-N,N,N-trimethylammoniumbromide)hexyl)fluorene-co-alt-4,7-(2,1,3-benzothiadiazole)] were exchanged with BF₄⁻, CF₃S0₃⁻, PF₆⁻, BPh₄⁻ and B(3,5-(CF₃)₂C₆H₃)₄⁻(BAr^{F}₄⁻). Absorption, photoluminescence and photoluminescence quantum yields were measured in water, dimethylsulfoxide (DMSO), methanol and in solid films cast from methanol. Largest variations in spectral features were observed in water and in the films. Examination of these trends, together with the spectral bandshapes in different solvents, suggests that increasing the counteranion (CA) size decreases interchain contacts and aggregation. Size analysis of polymers containing Br⁻ and BAr^{F}₄⁻ anions in water by dynamic light scattering techniques indicates suppression of aggregation in solution by the larger CA. Local current/voltage measurements of spun cast films at the nanoscale using conducting atomic force microscopy show that hole mobilities and charge injection barriers can be modulated by exchanging the CAs associated with CPs.

Embodiments of the invention include articles of manufacture which may comprise a plurality of individual devices utilizing salts of the invention. For example, a plurality of different LEDs comprising CPs with exchanged CAs can be used simultaneously in a display format. Multiplex embodiments may employ 2, 3, 4, 5, 10, 15, 20, 25, 50, 100, 200, 400, 1000, 5000, 10000, 50000, 200000, one million or more distinct articles provided by one or more embodiments described herein. Other aspects of the invention are discussed further herein.

Before the present invention is described in further detail, it is to be understood that this invention is not limited to the particular methodology, articles, compositions or apparatuses described, as such methods, articles, compositions or apparatuses can, of course, vary. It is also to be understood that the terminology used herein is for the purpose of describing particular embodiments only, and is not intended to limit the scope of the present invention.

Use of the singular forms “a,” “an,” and “the” include plural references unless the context clearly dictates otherwise. Thus, for example, reference to “a conjugated polymer” includes a plurality of conjugated polymers, reference to “a solvent” includes a plurality of such solvents, reference to “an LED” includes a plurality of LEDs, and the like. Additionally, use of specific plural references, such as “two,” “three,” etc., read on larger numbers of the same subject unless the context clearly dictates otherwise. The term “or” when used herein as the sole conjunction means “and/or” unless stated otherwise. The term “including” and related terms such as “includes” as used herein are not limiting and allow for the presence of elements in addition to those specifically recited.

Terms such as “connected,” “attached,” and “linked” are used interchangeably herein and encompass direct as well as indirect connection, attachment, linkage or conjugation unless the context clearly dictates otherwise.

Where a range of values is recited, it is to be understood that each intervening integer value, and each fraction thereof, between the recited upper and lower limits of that range is also specifically disclosed, along with each subrange between such values. The upper and lower limits of any range can independently be included in or excluded from the range, and all such ranges are encompassed within the invention. Where a value being discussed has inherent limits, for example where a component can be present at a concentration of from 0 to 100%, or where the pH of an aqueous solution can range from 1 to 14, those inherent limits are specifically disclosed as are ranges based on those inherent limits. Where a value is explicitly recited, it is to be understood that values which are about the same quantity or amount as the recited value are also within the scope of the invention, as are ranges based thereon with any other value as described herein.

Where a combination or group of elements is disclosed, each subset of those elements is also specifically disclosed and is within the scope of the invention. Conversely, where different elements or groups of elements are disclosed, combinations thereof are also disclosed.

Where any element of an invention is disclosed as having a plurality of alternatives, examples of that invention in which each alternative is excluded singly or in any combination with the other alternatives are also hereby disclosed; more than one element of an invention can have such exclusions, and all combinations of elements having such exclusions are hereby disclosed.

Unless defined otherwise or the context clearly dictates otherwise, all technical and scientific terms used herein have the same meaning as commonly understood by one of ordinary skill in the art to which this invention belongs. Although any methods and materials similar or equivalent to those described herein can be used in the practice or testing of the invention, the preferred methods and materials are now described.

All publications mentioned herein are hereby incorporated by reference for the purpose of disclosing and describing the particular materials and methodologies for which the reference was cited. The publications discussed herein are provided solely for their disclosure prior to the filing date of the present application. Nothing herein is to be construed as an admission that the invention is not entitled to antedate such disclosure by virtue of prior invention.

Definitions

In describing the present invention, the following terms will be employed, and are intended to be defined as indicated below.

“Alkyl” refers to a branched, unbranched or cyclic saturated hydrocarbon group of 1 to 24 carbon atoms optionally substituted at one or more positions, and includes polycyclic compounds. Examples of alkyl groups include optionally substituted methyl, ethyl, n-propyl, isopropyl, n-butyl, s-butyl, t-butyl, n-pentyl, isopentyl, neopentyl, n-hexyl, n-heptyl, n-octyl, n-decyl, hexyloctyl, tetradecyl, hexadecyl, eicosyl, tetracosyl and the like, as well as cycloalkyl groups such as cyclopropyl, cyclobutyl, cyclopentyl, cyclohexyl, cycloheptyl, cyclooctyl, adamantyl, and norbomyl. The term “lower alkyl” refers to an alkyl group of 1 to 6 carbon atoms, preferably 1 to 4 carbon atoms. Exemplary substituents on substituted alkyl groups include hydroxyl, cyano, alkoxy, ═O, ═S, —NO₂, halogen, haloalkyl, heteroalkyl, carboxyalkyl, amine, amide, thioether and —SH.

“Alkoxy” refers to an “—Oalkyl” group, where alkyl is as defined above. A “lower alkoxy” group intends an alkoxy group containing one to six, more preferably one to four carbon atoms.

“Alkenyl” refers to an unsaturated branched, unbranched or cyclic hydrocarbon group of 2 to 24 carbon atoms containing at least one carbon-carbon double bond and optionally substituted at one or more positions. Examples of alkenyl groups include ethenyl, 1-propenyl, 2-propenyl (allyl), 1-methylvinyl, cyclopropenyl, 1-butenyl, 2-butenyl, isobutenyl, 1,4-butadienyl, cyclobutenyl, 1-methylbut-2-enyl, 2-methylbut-2-en-4-yl, prenyl, pent-1-enyl, pent-3-enyl, 1,1-dimethylallyl, cyclopentenyl, hex-2-enyl, 1-methyl-1-ethylallyl, cyclohexenyl, heptenyl, cycloheptenyl, octenyl, cyclooctenyl, decenyl, tetradecenyl, hexadecenyl, eicosenyl, tetracosenyl and the like. Preferred alkenyl groups herein contain 2 to 12 carbon atoms. The term “lower alkenyl” intends an alkenyl group of 2 to 6 carbon atoms, preferably 2 to 4 carbon atoms. The term “cycloalkenyl” intends a cyclic alkenyl group of 3 to 8, preferably 5 or 6, carbon atoms. Exemplary substituents on substituted alkenyl groups include hydroxyl, cyano, alkoxy, ═O, ═S, —N0₂, halogen, halo alkyl, heteroalkyl, amine, thioether and —SH.

“Alkenyloxy” refers to an “—Oalkenyl” group, wherein alkenyl is as defined above.

“Alkyl aryl” refers to an alkyl group that is covalently joined to an aryl group. Preferably, the alkyl is a lower alkyl. Exemplary alkyl aryl groups include benzyl, phenethyl, phenopropyl, 1-benzylethyl, phenobutyl, 2-benzylpropyl and the like.

“Alkylaryloxy” refers to an “—Oalkylaryl” group, where alkyl aryl is as defined above.

“Alkynyl” refers to an unsaturated branched or unbranched hydrocarbon group of 2 to 24 carbon atoms containing at least one —C≡C— triple bond, optionally substituted at one or more positions. Examples of alkynyl groups include ethynyl, n-propynyl, isopropynyl, propargyl, but-2-ynyl, 3-methylbut-1-ynyl, octynyl, decynyl and the like. Preferred alkynyl groups herein contain 2 to 12 carbon atoms. The term “lower alkynyl” intends an alkynyl group of 2 to 6, preferably 2 to 4, carbon atoms, and one —C≡C— triple bond. Exemplary substituents on substituted alkynyl groups include hydroxyl, cyano, alkoxy, =0, ═S, —N0₂, halogen, haloalkyl, heteroalkyl, amine, thioether and —SH.

“Amide” refers to —C(O)NR′R″, where R′ and R″ are independently selected from hydrogen, alkyl, aryl, and alkylaryl.

“Amine” refers to an —N(R′)R″ group, where R′ and R″ are independently selected from hydrogen, alkyl, aryl, and alkylaryl.

“Aryl” refers to an aromatic group that has at least one ring having a conjugated π electron system and includes carbocyclic, heterocyclic, bridged and/or polycyclic aryl groups, and can be optionally substituted at one or more positions. Typical aryl groups contain 1 to 5 aromatic rings, which may be fused and/or linked. Exemplary aryl groups include phenyl, furanyl, azolyl, thiofuranyl, pyridyl, pyrimidyl, pyrazinyl, triazinyl, biphenyl, indenyl, benzofuranyl, indolyl, naphthyl, quinolinyl, isoquinolinyl, quinazolinyl, pyridopyridinyl, pyrrolopyridinyl, purinyl, tetralinyl and the like. Exemplary substituents on optionally substituted aryl groups include alkyl, alkoxy, alkylcarboxy, alkenyl, alkenyloxy, alkenylcarboxy, aryl, aryloxy, alkylaryl, alkylaryloxy, fused saturated or unsaturated optionally substituted rings, halogen, haloalkyl, heteroalkyl, —S(O)R, sulfonyl, —SO₃R, —SR, —NO₂, —NRR′, —OH, —CN, —C(O)R, —OC(O)R, —NHC(O)R, —(CH₂)ₙC0₂R or —(CH₂)ₙCONRR′ where n is 0-4, and wherein R and R′ are independently H, alkyl, aryl or alkylaryl.

“Aryloxy” refers to an “—Oaryl” group, where aryl is as defined above. “Carbocyclic” refers to an optionally substituted compound containing at least one ring and wherein all ring atoms are carbon, and can be saturated or unsaturated.

“Carbocyclic aryl” refers to an optionally substituted aryl group wherein the ring atoms are carbon.

“Conjugated” and “conjugated system” refers to molecular entities in which a group or chain of atoms bears valence electrons that are not-engaged in single-bond formation and that modify the behaviour of each other. Conjugated polymers are polymers exhibiting such delocalized bonding. Typically conjugated systems can comprise alternating single and double or multiple bonds form conjugated systems, and can be interspersed with atoms (e.g., heteroatoms) comprising nonbonding valence electrons. In some embodiments, conjugated polymers can comprise aromatic repeat units, optionally containing heteroatom linkages.

“Halo” or “halogen” refers to fluoro, chloro, bromo or iodo. “Halide” refers to the anionic form of the halogens.

“Halo alkyl” refers to an alkyl group substituted at one or more positions with a halogen, and includes alkyl groups substituted with only one type of halogen atom as well as alkyl groups substituted with a mixture of different types of halogen atoms. Exemplary halo alkyl groups include trihalomethyl groups, for example trifluoromethyl.

“Heteroalkyl” refers to an alkyl group wherein one or more carbon atoms and associated hydrogen atom(s) are replaced by an optionally substituted heteroatom, and includes alkyl groups substituted with only one type of heteroatom as well as alkyl groups substituted with a mixture of different types of heteroatoms. Heteroatoms include oxygen, sulfur, and nitrogen. As used herein, nitrogen heteroatoms and sulfur heteroatoms include any oxidized form of nitrogen and sulfur, and any form of nitrogen having four covalent bonds including protonated and alkylated forms. An optionally substituted heteroatom refers to a heteroatom having one or more attached hydrogens optionally replaced with alkyl, aryl, alkyl aryl and/or hydroxyl.

“Heterocyclic” refers to a compound containing at least one saturated or unsaturated ring having at least one heteroatom and optionally substituted at one or more positions. Typical heterocyclic groups contain 1 to 5 rings, which may be fused and/or linked, where the rings each contain five or six atoms. Examples of heterocyclic groups include piperidinyl, morpholinyl and pyrrolidinyl. Exemplary substituents for optionally substituted heterocyclic groups are as for alkyl and aryl at ring carbons and as for heteroalkyl at heteroatoms.

“Heterocyclic aryl” refers to an aryl group having at least 1 heteroatom in at least one aromatic ring. Exemplary heterocyclic aryl groups include furanyl, thienyl, pyridyl, pyridazinyl, pyrrolyl, N-lower alkyl-pyrrolo, pyrimidyl, pyrazinyl, triazinyl, tetrazinyl, triazolyl, tetrazolyl, imidazolyl, bipyridyl, tripyridyl, tetrapyridyl, phenazinyl, phenanthrolinyl, purinyl and the like.

“Hydrocarbyl” refers to hydrocarbyl substituents containing 1 to about 20 carbon atoms, including branched, unbranched and cyclic species as well as saturated and unsaturated species, for example alkyl groups, alkylidenyl groups, alkenyl groups, alkylaryl groups, aryl groups, and the like. The term “lower hydrocarbyl” intends a hydrocarbyl group of one to six carbon atoms, preferably one to four carbon atoms.

A “substituent” refers to a group that replaces one or more hydrogens attached to a carbon or nitrogen. Exemplary substituents include alkyl, alkylidenyl, alkylcarboxy, alkoxy, alkenyl, alkenylcarboxy, alkenyloxy, aryl, aryloxy, alkylaryl, alkylaryloxy, —OH, amide, carboxamide, carboxy, sulfonyl, ═O, ═S, —NO₂, halogen, halo alkyl, fused saturated or unsaturated optionally substituted rings, —S(O)R, —S0₃R, —SR, —NRR′, —OH, —CN, —C(O)R, —OC(O)R, —NHC(O)R, —(CH2)ₙCO₂R or —(CH₂)ₙCONRR′ where n is 0-4, and wherein R and R′ are independently H, alkyl, aryl or alkylaryl. Substituents also include replacement of a carbon atom and one or more associated hydrogen atoms with an optionally substituted heteroatom.

“Sulfonyl” refers to —S(O)₂R, where R is alkyl, aryl, —C(CN)═C-aryl, —CH₂CN, alkylaryl, or amine.

“Thioamide” refers to —C(S)NR′R″, where R′ and R″ are independently selected from hydrogen, alkyl, aryl, and alkylaryl.

“Thioether” refers to —SR, where R is alkyl, aryl, or alkylaryl.

“Multiplexing” herein refers to an assay or other analytical method in which multiple analytes can be assayed simultaneously.

“Optional” or “optionally” means that the subsequently described event or circumstance mayor may not occur, and that the description includes instances where said event or circumstance occurs singly or multiply and instances where it does not occur at all. For example, the phrase “optionally substituted alkyl” means an alkyl moiety that may or may not be substituted and the description includes both unsubstituted, monosubstituted, and polysubstituted alkyls.

The Conjugated Polyelectrolytes

Conjugated polyelectrolytes (CPs) are provided and can be used in embodiments described herein. The CPs comprise ionic groups linked to a conjugated polymer, which can increase solubility in polar media. Any or all of the subunits of the CP may comprise one or more pendant ionic groups. Any suitable ionic groups may be incorporated into CPs. Exemplary cationic groups which may be incorporated include ammonium groups, guanidinium groups, histidines, polyamines, pyridinium groups, and sulfonium groups. Exemplary anionic groups include sulfates, sulfonates, carboxylates, and nitrates.

The ionic group may be linked to the conjugated polymer backbone by a linker, preferably an unconjugated linker, for example alkyl groups, polyethers, alkylamines, and/or polyamines.

One synthetic approach to introducing a charged group into a conjugated polymer is as follows. A neutral polymer is first formed by the Suzuki coupling of one or more bis- (or tris- etc.) boronic acid-substituted monomer(s) with one or more monomers that have at least two bromine substitutions on aromatic ring positions. Bromine groups are attached to any or all of the monomers via linkers. Conversion to cationic water-soluble polymers is accomplished by addition of condensed trimethylamine, which replaces the pendant bromines with ammonium groups. Methods of synthesizing polyanionic conjugated polymers (e.g., polysulfonates, polycarboxylates) are also known in the art.

The CP can be a copolymer, and may be a block copolymer, a graft copolymer, or both. The solubilizing functionalities and/or the conductive subunits may be incorporated into the CP randomly, alternately, periodically and/or in blocks.

Exemplary polymers which may form the backbone of the compounds of the present invention include, for example, polypyrroles, polyfluorenes, polyphenylene [symbol] vinylenes, polythiophenes, polyisothianaphthenes, polyanilines, poly(fluorene-alt [symbol] benzothiadiazole), polyvinylcarbazole, poly(fluorene phenylene), poly(fluorene triphenylamine), poly-p-phenylenes and copolymers thereof, all or which can be optionally substituted. Exemplary repeat units which may be incorporated include benzothiadiazole, oxadiazole, quinoxaline, cyano-substituted olefins, squaric acid, maleimide, 9,9-dialkylfluorenes, 2,5-dimethyl-1,4-phenylidene, 2,5-dioctyloxy-1,4-phenylidene, and terthiophenes, all of which may also be substituted. Other exemplary polymeric subunits and repeating units are shown in the accompanying tables.

TABLE 1
Typical aromatic repeat units for the construction of conjugated segments
and oligomeric structures.

| | | |
|---|---|---|
| 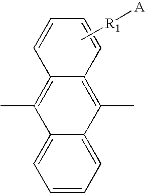 | 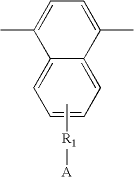 | 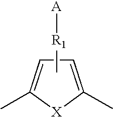 |

| | |
|---|---|
| 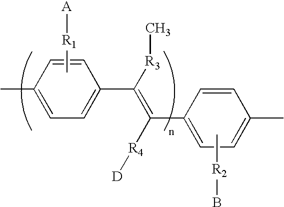 | 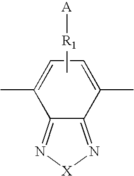 |

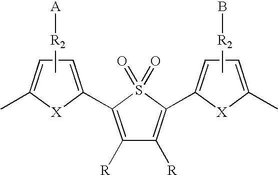

| | |
|---|---|
| 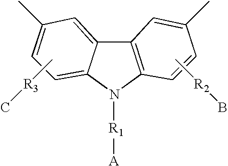 | 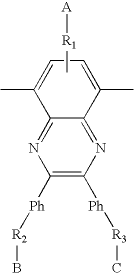 |

| | |
|---|---|
| 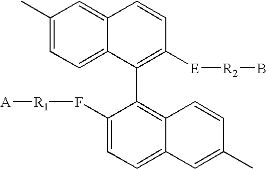 | 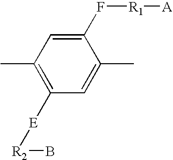 |

| | |
|---|---|
| 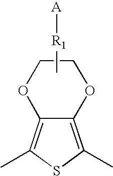 | 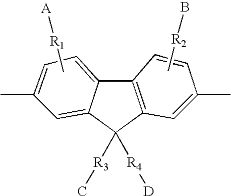 |

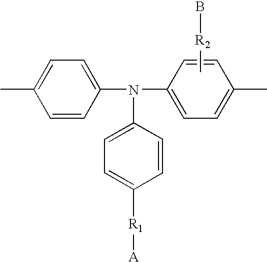

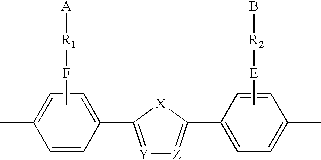

TABLE 2
Typical aromatic repeat units for the construction of conjugated segments
and oligomeric structures.

| | |
|---|---|
| 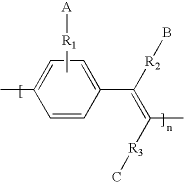 | 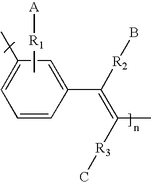 |

| | |
|---|---|
| 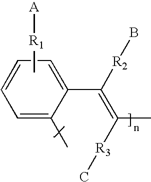 | 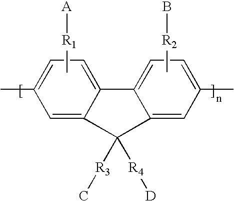 |

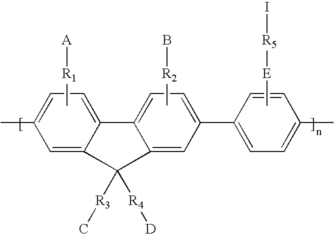

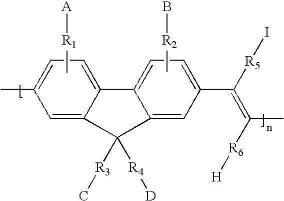

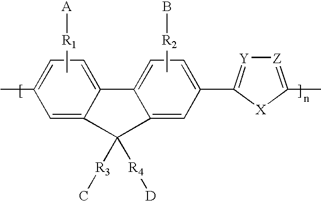

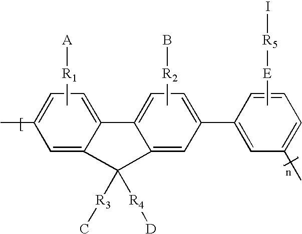

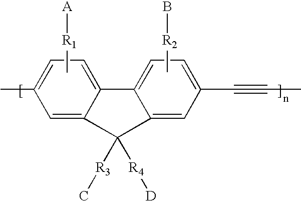

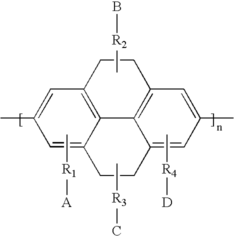

| | |
|---|---|
| 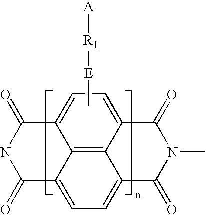 | 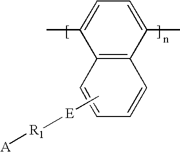 |

| | |
|---|---|
| 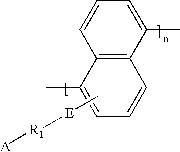 | 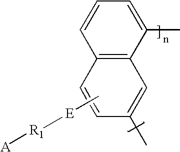 |

| | |
|---|---|
| 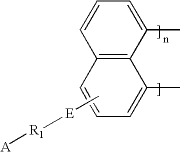 | 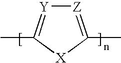 |

| | |
|---|---|
| 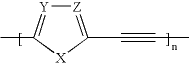 | 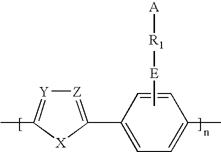 |

| | |
|---|---|
| 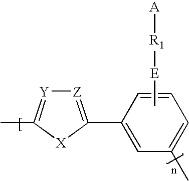 | 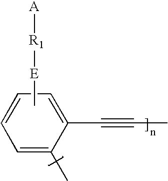 |

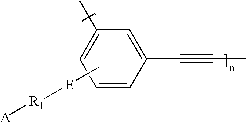

| | |
|---|---|
| 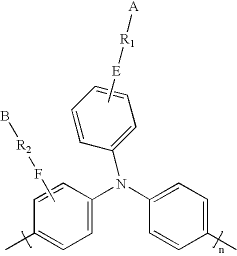 | 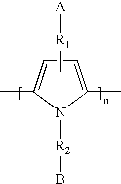 |

| | |
|---|---|
| 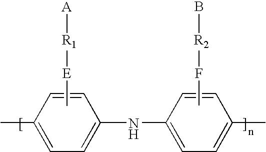 | 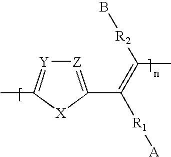 |

| | |
|---|---|
| 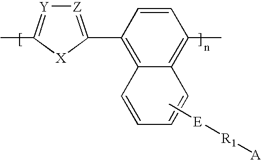 | 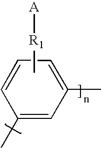 |

| | | |
|---|---|---|
| 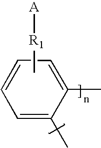 | 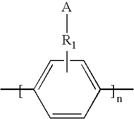 | 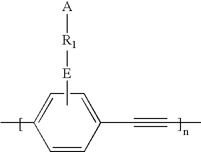 |

| | |
|---|---|
| 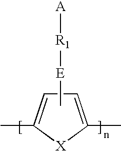 | 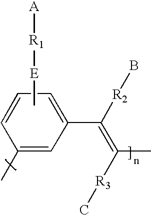 |

| | |
|---|---|
| 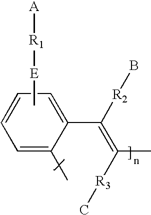 | 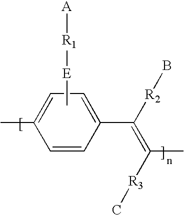 |

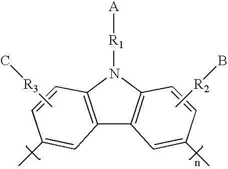

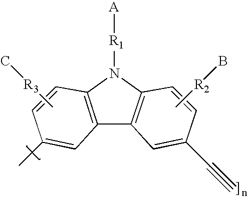

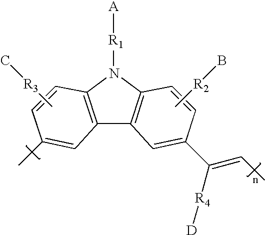

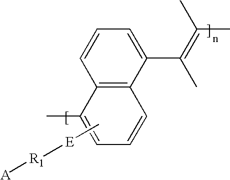

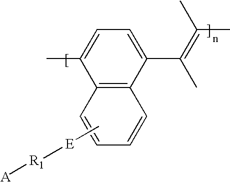

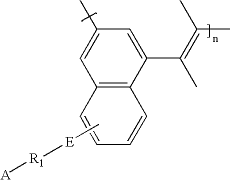

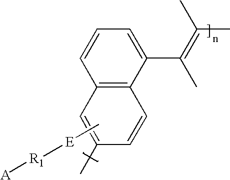

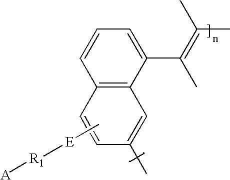

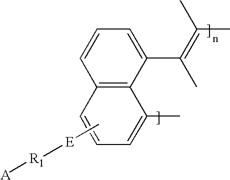

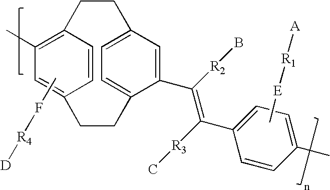

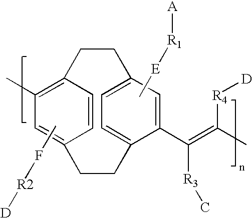

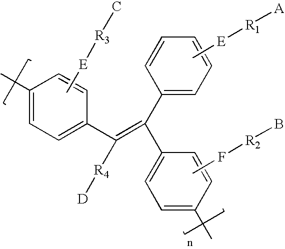

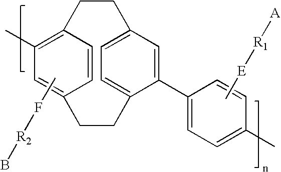

The CP can contain a sufficient density of ionic functionalities to render the overall polymer soluble in a polar medium. The CP preferably contains at least about 0.01 mol % of the repeat units substituted with at least one ionic group, and may contain at least about 0.02 mol %, at least about 0.05 mol %, at least about 0.1 mol %, at least about 0.2 mol %, at least about 0.5 mol %, at least about 1 mol %, at least about 2 mol %, at least about 5 mol %, at least about 10 mol %, at least about 20 mol %, or at least about 30 mol %. The CP may contain up to 100 mol % of the ionic group, and may contain about 99 mol % or less, about 90 mol % or less, about 80 mol % or less, about 70 mol % or less, about 60 mol % or less, about 50 mol % or less, or about 40 mol % or less.

In some embodiments, the CPs described herein are soluble in aqueous solutions and other highly polar solvents, and can be soluble in water. By “water-soluble” is meant that the material exhibits solubility in a predominantly aqueous solution, which, although comprising more than 50% by volume of water, does not exclude other substances from that solution, including without limitation buffers, blocking agents, co solvents, salts, metal ions and detergents.

For cationic CPs, the aromatic repeat units, polymeric segments and oligomeric structures can be optionally substituted at one or more positions with one or more groups selected from —R₁-A, —R₂—B, —R₃—C and —R₄-D, which may be attached through bridging functional groups -E- and —F—, with the proviso that the polymer as a whole must be substituted with a plurality of cationic groups.

R₁, R₂, R₃ and R₄ are independently selected from alkyl, alkenyl, alkoxy, alkynyl, and aryl, alkyl aryl, aryl alkyl, and polyalkylene oxide, each optionally substituted, which may contain one or more heteroatoms, or may be not present. R₁, R₂, R₃ and R₄ can be independently selected from C₁₋₂₂ alkyl, C₁₋₂₂ alkoxy, C₁₋₂₂ ester, polyalkylene oxide having from 1 to about 22 carbon atoms, cyclic crown ether having from 1 to about 22 carbon atoms, or not present. Preferably, R₁, R₂, R₃ and R₄ may be selected from straight or branched alkyl groups having 1 to about 12 carbon atoms, or alkoxy groups with 1 to about 12 carbon atoms. It is to be understood that more than one functional group may be appended to the rings as indicated in the formulas at one or more positions.

A, B, C and D are independently selected from H, —SiR′R″R′″, —N⁺R′R″R′″, a guanidinium group, histidine, a polyamine, a pyridinium group, and a sulfonium group. R′, R″ and R′″ are independently selected from the group consisting of hydrogen, C₁₋₁₂ alkyl and C₁₋₁₂ alkoxy and C₁₋₁₂ cycloalkyl. It is preferred that R′, R″ and R′″ are lower alkyl or lower alkoxy groups. (Similar anionic CPs can be made where A, B, C, and D are anionic groups, for example sulfate, sulfonate, phosphate, phosphonate, carboxylate, and nitrate).

E and F are independently selected from not present, —O—, —S—, —C(O)—, —C(O)O—, —C(R)(R′)—, —N(R′)—, and —Si(R′)(R″), wherein R′ and R″ are as defined above.

X is O, S, Se, —N(R′)— or —C(R′)(R″)—, and Y and Z are independently selected from —C(R)═ and —N═, where R, R′ and R″ are as defined above.

The CPs can comprise end-capping units which may be the same or different. The capping units may be activated units that allow further chemical reaction to extend the polymer chain, or may be nonactivated termination units. The capping units can be independently selected from hydrogen, optionally substituted aryl, halogen substituted aryl, boronic acid substituted aryl, and boronate radical substituted aryl.

In some embodiments, the CP is one that comprises “low bandgap repeat units” of a type and in an amount that contribute an absorption to the polymer in the range of about 450 nm to about 1000 nm. The low bandgap repeat units may or may not exhibit such an absorption prior to polymerization, but does introduce that absorption when incorporated into the conjugated polymer. Incorporation of repeat units that decrease the band gap can produce conjugated polymers with such characteristics. Exemplary optionally substituted species which result in polymers that absorb light at such wavelengths include 2,1,3-benzothiadiazole, benzoselenadiazole, benzotellurodiazole, naphthoselenadiazole, 4,7-di(thien-2-yl)-2,1,3-benzothiadiazole, squaraine dyes, quinoxalines, low bandgap commercial dyes, olefins, and cyano-substituted olefins and isomers thereof. For example, 2,7-carbazolene-vinylene conjugated polymers have been described with peak absorptions ranging from about 455-485 nm [5]. Polymers can be prepared incorporating benzoselenadiazole with absorption maxima at 485 nm. Similarly, polymers incorporating naphthoselenadiazole are known with absorption maxima at 550 nm. Polymers incorporating 4,7-di(thien-2-yl)-2,1,3-benzothiadiazole are known with absorption maxima at about 515 nm. Polymers incorporating cyanovinylenes are known with peak absorptions in this region, for example from 372-537 nm, and exhibiting absorption above 700 nm (PFR(1-4)-S, reference 6). Preparation of polymers incorporating monomers that provide absorption in the spectral region up to 1000 nm has been described [7;8] The polymer may include 15 mol %, 20 mol %, 25 mol %, 30 mol %, 35 mol %, 40 mol %, 45 mol %, 50 mol %, 55 mol %, 60 mol %, 65 mol %, 70 mol %, 75 mol %, 80 mol %, 85 mol %, 90 mol %, 95 mol %, or more of the low bandgap repeat unit.

Ion Exchange and Salts Comprising Exchanged Counterions

Methods of altering properties of conjugated polyelectrolytes are provided. The methods comprise exchanging a plurality of counterions associated with a polyionic conjugated polymer with substitute or replacement counterion.

By “exchanging,” “replacing,” “substituting” and the like with relation to the counterions associated with a polyionic conjugated polymer is meant exchanging at least 80% of the counterions associated with the CP. Preferably at least 85% of the CAs are exchanged, more preferably at least 90%, and most preferably 95% or more of the CAs are exchanged. In some cases there may be no detectable levels of the original CAs associated with the CPs. Counterion association can be determined by any suitable technique, for example by XPS spectroscopy.

The counterions may be exchanged by any appropriate method known or discoverable in the art. Exemplary ion exchange methods include mass action, dialysis, chromatography, and electrophoresis. After ion exchange, the new salt form of the CP can optionally be purified and/or isolated. Any suitable method(s) that leads towards the purification and/or isolation of the polymer salt of interest can be used. Exemplary methods include crystallization, chromatography (e.g., exclusion, HPLC, FPLC), precipitation, extraction.

The charged moiety may range from a single atom sufficiently oxidized or reduced to bear a charge, or a cyclic structure containing a distributed charge.

The counterion may contain one or more such charge-distributing moieties which serve to distribute the charge carried by the charge-carrying moiety, and thereby make it more diffuse and/or distributed over a larger region. Without wishing to be bound by theory, it appears that distributing the charge over a larger counterion inhibits aggregation of the conjugated polyionic polymer, thereby allowing useful control of this property in a variety of settings.

Charge-distributing moieties may include cyclic or polycyclic structures, including optionally substituted aryl groups.

In some embodiments, the CAs may contain 5, 6, 7, 8, 9, 10 or more atoms through which the electronic charge is distributed.

Where the counterion is anionic, the counterion can comprise one or more electron withdrawing moieties that serve to distribute negative charge diffusely throughout the molecule. Exemplary electron withdrawing species include halogens, haloalkyl groups, fluoroalkyl groups, —C(O)R, —CN, —NO₂, other oxidized groups, and other electronegative groups.

Where the counterion is cationic, the counterion can contain electron donating groups that serve to distribute positive charge diffusely throughout the molecule. Exemplary electron donating species include alkyl, alkoxy, hydroxyl, —O-linked esters, amine and amine derivatives (e.g., —N-linked amides).

Exemplary counterions of interest include the following ionic species: borates, including optionally substituted aryl borates, coordination complexes, organometallic complexes, and other charged cyclic and polycyclic species, including aryl and polyaryl species. Those counterions comprising additional charge-distributing moieties are of particular interest for some purposes.

Counterions may provide one or more alterations to the electrical, electroluminescent and/or photoluminescent properties of ionic conjugated polymers.

In some aspects, the present invention is directed to the methods of exchange counteranions of cationic conjugated polyelectrolytes and oligomers. These cationic conjugated polymers can feature ionic side groups which render the polymers soluble in water and other high polar solvents. In the present invention, the polyelectrolytes typically contain halide ions such as chloride (Cl⁻), bromide (Br⁻) and iodide (I⁻) as counteranions to compensate for the charge of the cationic pendant groups. The cationic groups on their pendant groups may be monovalent, or multivalent, such as ammonium, phosphonium, imidazolium, ruthenium complex, etc.

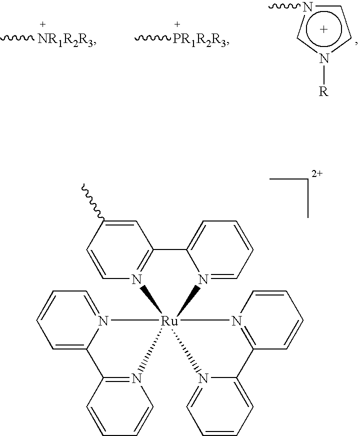

In some embodiments, the cationic conjugated polymers are homopolymers or copolymers containing one or more backbone structures, like, polyfluorenes, polycarbazole, poly(p-phenylene), poly(phenylenevinelye), polythiophene, poly(spiro-phenylene), ladder poly(p-phenylene) (Scheme 1). R, R₁, R₂, R₃, R₄, and R₅ are independently in each occurrence hydrogen, C₁₋₂₀ hydrocarbyl, C₁₋₂₀ hydrocarbyloxy, and each polymer at least has one side chain with C₁₋₂₀ hydrocarbyl, C₁₋₂₀ hydrocarbyloxy which terminated in above described cations, such as ammonium, phosphonium, imidazolium, ruthenium complex, etc, and the counteranion was halide ions.

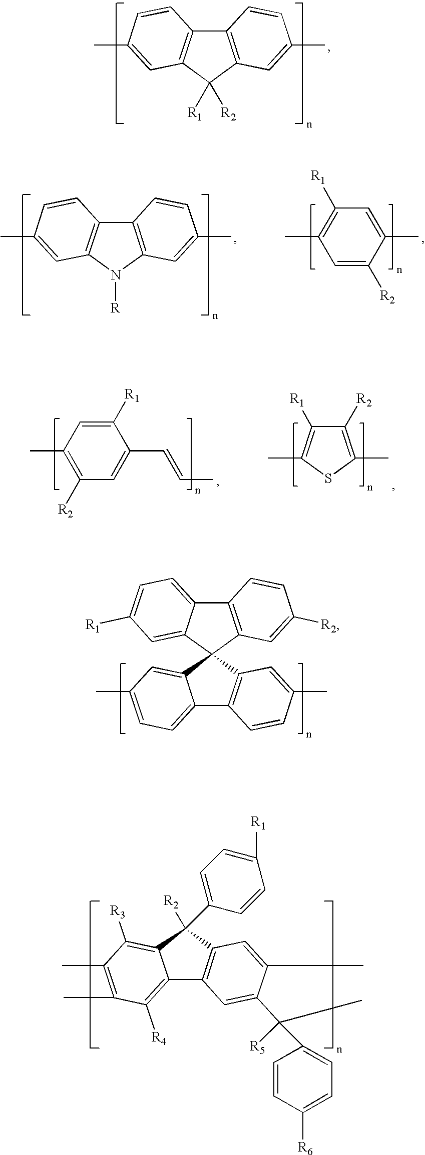

The copolymers can contain one or more the above structures, and may contain one or more of the following structures. R, R₁, and R₂ are independently in each occurrence hydrogen, C₁₋₂₀ hydrocarbyl, C₁₋₂₀ hydrocarbyloxy, and it is possible that above described cations terminated the side chain.

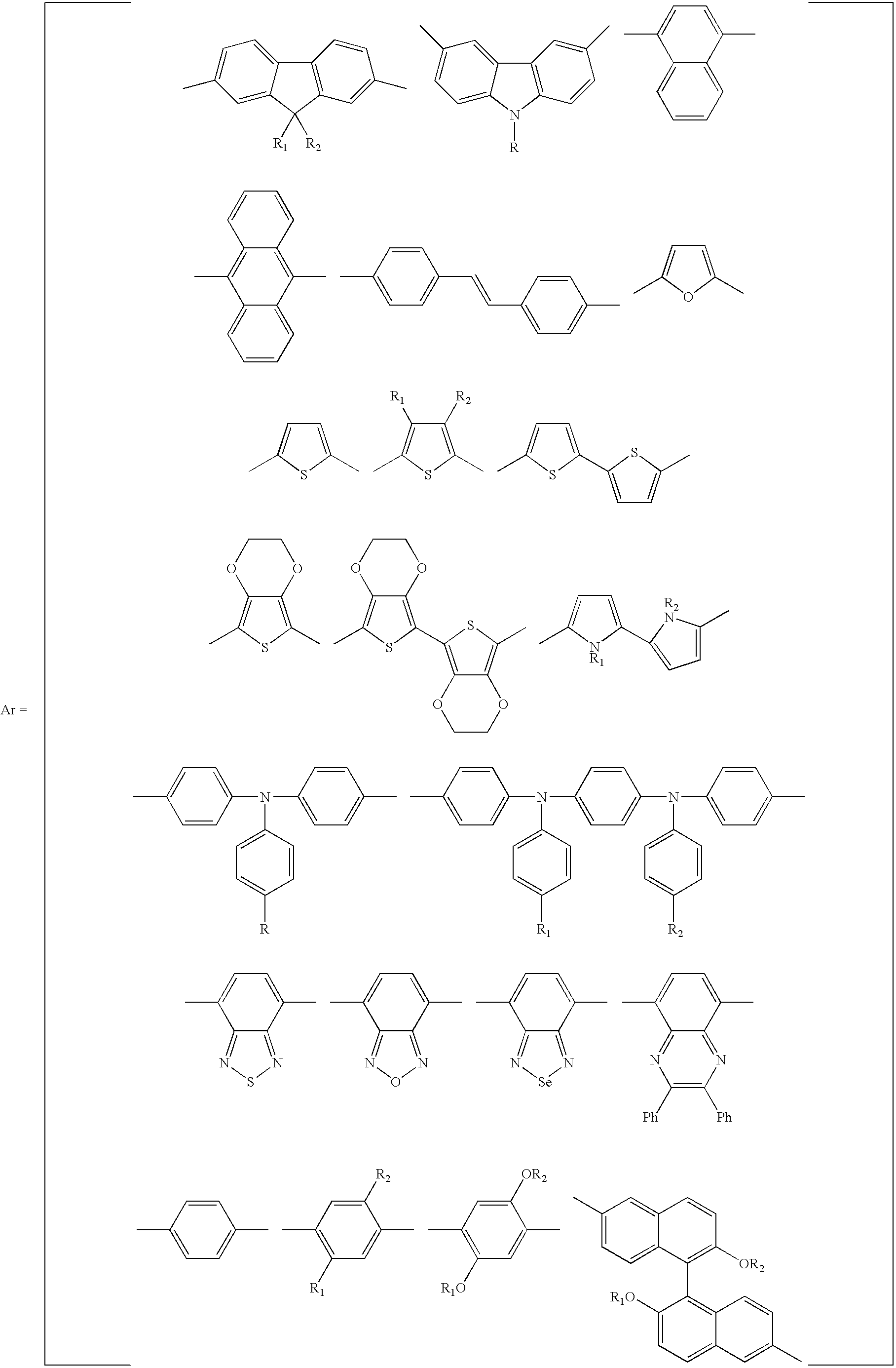

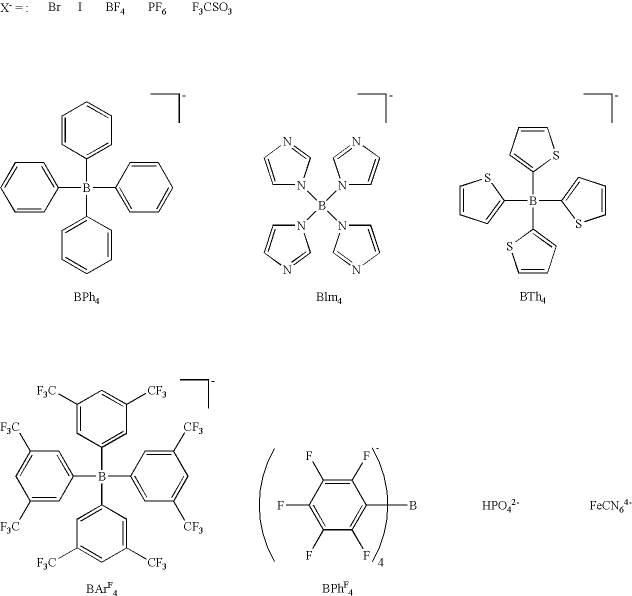

CPs with exchanged counterions may also be provided in purified form. Any available method or combination of methods may be used for purification. Exemplary methods include precipitation, washing, extraction, column chromatography, and sublimation (for smaller oligomers). Solutions of the CP and exchanged counterions are also provided. Solutions may be provided in a container of any suitable form. Solutions may be packaged in a container designed for incorporation into a solution processing apparatus, for example a printer. In some embodiments, the solution may be provided in an inkjet cartridge designed to be used with an inkjet printer.

In certain embodiments, a polar solvent can be used in a solution of a CP with an exchanged counterion formed therefrom in some embodiments is wettable on the surface to which it is to be applied, such that when it is deposited it flows generally uniformly and evenly over the surface, and preferably is controllable in thickness. Combinations of solvents may also be used. Preferably the solvent is sufficiently wettable on the substrate that the solution spreads appropriately when deposited thereon. One or more wetting agents may be included in the solution to improve its ability to wet a surface and/or lowers its surface tension. For example, a solution comprising water may have an alcohol, a surfactant, or a combination of materials added thereto serving as wetting agents.

Methods of Use

The salts described herein can be used in a variety of methods. Methods of particular interest include deposition of the salts into electronic devices, particularly in devices comprising multiple layers of conjugated polymers. Any of a variety of deposition methods can be used in a given device, including without limitation vacuum sputtering (RF or Magnetron), electron beam evaporation, thermal vapor deposition, chemical deposition, sublimation, and solution processing methods. Any deposition method known or discoverable in the art can be used to deposit the soluble polar polymers provided herein, although solution methods are currently preferred.

These layers are commonly deposited by spin-coating, drop-casting, sequential spin-casting, formation of Langmuir-Blodgett films or electrostatic adsorption techniques. Articles of manufacture maybe fabricated by stepwise deposition of polymer layers; the water solubility of CPs provided herein allows for the sequential deposition of layers of different materials with different solubilities, providing certain advantages during manufacturing, including for the deposition of thin layers of material.

In particular embodiments, solution processing methods can be used to incorporate CPs into an article of manufacture. Printing techniques may advantageously be used to deposit the CPs, e.g., inkjet printing, offset printing, etc.

Where the CPs and salts thereof are used in multilayer devices comprising multiple conjugated polymeric layers, one or more of these layers may comprise nonpolar conjugated polymers which may not be soluble in a polar medium of interest. These include, for example, MEH-PPV, P3ATs [poly(3-alkylthiophenes), where alkyl is from 6 to 16 carbons], such as poly(2,5-dimethoxy-p-phenylene vinylene)-“PDMPV”, and poly(2,5-thienylenevinylene); poly(phenylenevinylene) or “PPV” and alkoxy derivatives thereof; PFO, PFO-BT, and polyanilines. The nonpolar conjugated polymer can be deposited by any suitable technique; in some embodiments it is deposited or cast directly from solution. Typically, organic solvents are used, typically with low polarity. Exemplary organic solvents include: halohydrocarbons such as methylene chloride, chloroform, and carbon tetrachloride; aromatic hydrocarbons such as xylene, benzene, toluene; and other hydrocarbons including decaline.

Mixed solvents can also be used. The differing solubility properties of nonpolar and polar polymers allow for deposition of multiple polymeric layers via solution processing methods, which can simplify manufacturing and reduce costs. The water-soluble polymers described herein allow for the solution deposition of alternating layers of polymers of differing solubilities to form bilayer or multilayer devices.

When depositing the conjugated polymer on a substrate, the solution can be relatively dilute, such as from 0.1 to 20% w/w in concentration, especially 0.2 to 5% w. In some embodiments, film thicknesses may be at least about 50, 100, or 200 nm. In some embodiments, film thicknesses of less than about 400, 200, or 100 nm can be used. In some embodiments, film thicknesses of about 10 nm, about 20 nm, about 30 nm, about 40 nm, or less, are used.

The polymer solution can be formed into a selected shape if desired, e.g. a fiber, film or the like by any suitable method, for example extrusion.

After deposition of a solution comprising a conjugated polymer, the solvent is removed. Any available method or combination of methods may be used for removing the solvent. Exemplary solvent removal methods include evaporation, heating, extraction, and subjecting the solution to a vacuum, and combinations comprising any thereof.

In some embodiments, the conjugated polymer may be deposited on a substrate. The substrate can comprise a wide range of material, either biological, nonbiological, organic, inorganic, or a combination of any of these. In some embodiments, the substrate can be transparent. The substrate can be a rigid material, for example a rigid plastic or a rigid inorganic oxide. The substrate can be a flexible material, for example a transparent organic polymer such as polyethyleneterephthalate or a flexible polycarbonate. The substrate can be conductive or nonconductive.

The CPs can be deposited on a substrate in any of a variety of formats. For example, the substrate may be a polymerized Langmuir Blodgett film, functionalized glass, Si, Ge, GaAs, indium doped GaN, GaP, SiC [9], Si0₂, SiN₄, semiconductor nanocrystals, modified silicon, or any of a wide variety of gels or polymers such as (poly)tetrafluoroethylene, (poly)vinylidenedifluoride, polystyrene, cross-linked polystyrene, polyacrylic, polylactic acid, polyglycolic acid, poly(lactide coglycolide), polyanhydrides, poly(methyl methacrylate), poly(ethylene-co-vinyl acetate), polyethyleneterephthalate, polysiloxanes, polymeric silica, latexes, dextran polymers, epoxies, polycarbonates, agarose, poly(acrylamide) or combinations thereof. Conducting polymers and photoconductive materials can be used. The substrate can take the form of a photodiode, an optoelectronic sensor such as an optoelectronic semiconductor chip or optoelectronic thin-film semiconductor, or a biochip.

The CPs comprising exchanged salts may be used in methods which screen for a property of interest. For example, the materials may be tested for increased fluorescent efficiency, for absorbance wavelength, emission wavelength, conductive properties, ability to inject and/or transport electrons, ability to block holes, ability to inject and/or transport holes, and/or work function, charge injection, and other properties described herein.

Articles of Manufacture

The CPs comprising exchanged salts can be incorporated into any of various articles of manufacture including optoelectronic or electronic devices, biosensors, diodes, including photo diodes and light-emitting diodes (“LEDs”), optoelectronic semiconductor chips, semiconductor thin-films, and chips, and can be used in array or micro array form. The polymer can be incorporated into a polymeric photoswitch. The polymer can be incorporated into an optical interconnect or a transducer to convert a light signal to an electrical impulse. The CPs can serve as liquid crystal materials. The CPs may be used in electrochemical cells, light-emitting electrochemical cells (LECs), solar cells, photovoltaics, as conductive layers in electrochromic displays, in field effect transistors, and in Schottky diodes.

The CPs can be used as lasing materials. Optically pumped laser emission has been reported from MEH-PPV in dilute solution in an appropriate solvent, in direct analogy with conventional dye lasers [10;11]. Semiconducting polymers in the form of neat undiluted films have been demonstrated as active luminescent materials in solid state lasers [12;13]. The use of semiconducting polymers as materials for solid state lasers is disclosed [14]. In semiconducting polymers, the emission is at longer wavelengths than the onset of significant absorption (the Stokes shift) resulting from inter- and intramolecular energy transfer. Thus there is minimal self-absorption of the emitted radiation [12], so self-absorption does not make the materials lossy. Moreover, since the absorption and emission are spectrally separated, pumping the excited state via the π to π* transition does not stimulate emission, and an inverted population can be obtained at relatively low pump power.

Light-emitting diodes can be fabricated incorporating one or more layers of CPs, which may serve as conductive layers. Light can be emitted in various ways, e.g., by using one or more transparent or semitransparent electrodes, thereby allowing generated light to exit from the device.

The mechanism of operation of a polymer LED requires that carrier injection be optimized and balanced by matching the electrodes to the electronic structure of the semiconducting polymer. For optimum injection, the work function of the anode should lie at approximately the top of the valence band, Ev, (the π-band or highest occupied molecular orbital, HOMO) and the work function of the cathode should lie at approximately the bottom of the conduction band, Ec, (the π*-band or lowest unoccupied molecular orbital, LUMO).

LED embodiments include hole-injecting and electron-injecting electrodes. A conductive layer made of a high work function material (above 4.5 eV) may be used as the hole-injecting electrode. Exemplary high work function materials include electronegative metals such as gold or silver, and metal-metal oxide mixtures such as indium-tin oxide. An electron-injecting electrode can be fabricated from a low work function metal or alloy, typically having a work function below 4.3. Exemplary low work function materials include indium, calcium, barium and magnesium. The electrodes can be applied by any suitable method; a number of methods are known to the art (e.g. evaporated, sputtered, or electron-beam evaporation).

Multi-layer PLEDs can be made using one or more layers comprising a salt comprising a CP and an exchanged counterion (red, green or blue emitting), cast from solution in an organic solvent, as the emissive layer and a water-soluble (or methanol-soluble) cationic conjugated copolymer as electron-transport layer. The emitting layer may optionally have one, two or more organometallic emitters incorporated. LEDs with output in the red, blue, or green can be prepared comprising the salts provided herein, as well as white-emitting LEDs. The device geometry and deposition order can be selected based on the type of conductive polymer being used. More than one type of conductive polymer can be used in the same multilayer device. A multilayer device may include more than one layer of electron-injecting conjugated polymers, more than one layer of hole-injecting conjugated polymers, or at least one layer of a hole-injecting polymer and at least one layer of an electron-injecting conjugated polymer.

In PLEDs, the device efficiency is reduced by cathode quenching since the recombination zone is typically located near the cathode. [20] The addition of an ETL moves the recombination zone away from the cathode and thereby eliminates cathode quenching. In addition, the ETL can serve to block the diffusion of metal atoms, such as barium and calcium, and thereby prevents the generation of quenching centers [20] during the cathode deposition process.

In some embodiments, the principal criteria when a soluble conjugated polymer is used as an electron transport layer (ETL) in polymer light-emitting diodes (PLEDs) are the following: (1) The lowest unoccupied molecular orbital (LUMO) of the ETL must be at an energy close to, or even within the π*-band of the emissive semiconducting polymer (so electrons can be injected); and (2) The solvent used for casting the electron injection material must not dissolve the underlying emissive polymer. By “close to” is meant within about 1 eV of the π*-band.

Similarly, the principal criteria for a polymer based hole transport layer (HTL) for use in polymer light-emitting diodes (PLEDs) is that the highest occupied molecular orbital (HOMO) of the HTL must be at an energy close to, or even within the valence band of the emissive semiconducting polymer. By “close to” is meant within about 1 eV of the valence band.

Solubility considerations can dictate the deposition order of the particular CPs and solvents used to produce a desired device configuration. Any number of layers of CPs with different solubilities may be deposited via solution processing by employing these techniques.

The emissive layer in some embodiments of LEDs employing one or more salts provided as described herein can comprise a blend (mixture) of one or more emitting polymers (or copolymers) with one or more organometallic emitters. Preferred emitting polymers are generally conjugated. Examples include devices made from PFO or poly(9,9-dioctylfluorene) end-capped with 5-biphenyl-1,3,4-oxadiazol (PFO-ETM) blended with tris(2,5-bis-2′-(9′,9′-dihexylfluorene)pyridine)iridium (III), (Ir(HFP)₃) and devices made from blends of PFO-ETM with poly(9,9-dioctylfluorene-co-fluorenone) with 1% fluorenone (PFO-F(1%)) and Ir(HFP)₃. The synthesis of PFO-ETM has been reported in the literature [15]. Other emitting polymers and especially blue-emitting polymers can also be used in the practice of the invention. The synthesis of Ir(HFP)₃ has been reported in the scientific literature [16]. The synthesis of PFO-F(1%) was also reported [17]. Ir(HFP)₃ is representative of the useful organometallic emitters which are complexes and compounds having Ir, Pr, Os, Ru or Au or the like as a center atom.

High-performance PLEDs based on an emissive layer comprising PFO-ETM as host and organometallic emitters as guests have been previously demonstrated. [15;18;19].

The electron injection/transport layer (EIL/ETL), typically 20 to 30 nm thick, can be cast from solution onto one surface of the emissive layer. The electron injection/transport layer is fabricated from a semiconducting organic polymer material with a relatively large electron affinity; i.e. with a lowest unoccupied molecular orbital (LUMO) close in energy to that of the bottom of the π*-band of the luminescent polymer in the emissive layer, for example within about 1 eV. The EIL/ETL can be fabricated from a material having a LUMO closer to the LUMO of the emissive layer than the work function of the low work function electron injection electrode. Examples include t-Bu-PBD SO₃Na [20]. This layer can be cast from a polar solvent-based solution such as an aqueous and/or lower alkanol solution.

The hole transport layer (HTL), typically 20 to 30 nm thick, is cast from solution adjacent to hole injection layer. If the hole injection electrode is a single layer anode, then the HTL will be deposited directly on the electrode. The hole injection/transport layer is fabricated from a semiconducting organic polymer material with a relatively small ionization potential; i.e., with highest occupied molecular orbital (HOMO) close in energy to that of the top of the n-band of the luminescent polymer in the emissive layer, for example within about 1 eV. Preferably the HTL is fabricated from a material having a HOMO closer to the HOMO of the emissive layer than the work function of the hole injection electrode. Examples include PVK—SO₃Li [21]. This layer is cast from a polar solvent-based solution such as an aqueous and/or lower alkanol solution.

The devices of the invention may include a bilayer anode. One layer of a bilayer anode is generally referred to as a “Hole Injection Layer” or “HIL.” If such a layer is present, then this layer will be referred to as a “Hole Transport Layer” or “HTL.” If a separate Hole Injection Layer is not present then this layer can serve both functions and can be referred to as a “Hole Injection Transport Layer” or “HIL/HTL.”

When a hole injection layer is present to provide a bilayer anode, it is typically 20 to 30 nm thick and is cast from solution onto the electrode. Examples of materials used include semiconducting organic polymers such as PEDOT:PSS cast from a polar (aqueous) solution or the precursor of poly(BTPD-Si-PFCB) [19;23].

The high work function hole injection electrode is typically a transparent conductive metal-metal oxide or sulfide material such as indium-tin oxide (ITO) with resistivity of 20 ohm/square or less and transmission of 89% or greater @ 550 nm. Other materials are available such as thin, transparent layers of gold or silver. This electrode is commonly deposited on the solid support by thermal vapor deposition, electron beam evaporation, RF or Magnetron sputtering, chemical deposition or the like. These same processes can be used to deposit the low work-function electrode as well. The principal requirement of the high work function electrode is the combination of a suitable work function, low resistivity and high transparency.

The low work function electrode of an LED serves as an electron injection contact. It is typically made of a low work function metal or alloy placed on the opposite side of the active emissive polymeric layer from the high work function electrode. Low work function metals in the context of the present invention include materials with a work function of about 4.3 eV or less and are known in the art to include, for example Ba, Ca, Mg, In and Tb. They are often accompanied by a layer of stable metal such as Ag, Au, Al or the like. This serves as a protection layer on top of reactive materials such as Ba, Ca, Tb. Other low work function (low ionization potential) conducting materials can be used in place of a conventional metal as the electron injection contact. The thickness of the electron injection electrode film is not critical and can be adjusted to achieve the desired surface resistance (surface resistance or sheet resistance is defined as the resistivity divided by the thickness) and can typically vary in the range of from significantly less than 100 Å to about 2000 Å or more. These materials are generally laid down as thin films with the techniques set out in the description of the high work function electrode. In some embodiments, salts provided by the current invention can be used as electron transport layers and permit the use of Al directly without a layer of a low work function metal such as Ba or Ca.

The various layers are usually supported by a solid substrate. This can be a rigid material such as plastic, glass, silicon, ceramic or the like or a flexible material such as a flexible plastic as well. This support may be transparent, in which case the light can be emitted through it and through the transparent electrode. Alternatively, the support can be non-transparent, in which case the transparent electrode through which light is emitted is on the surface of the emissive layer away from the support.

The passivation (protection) layer on the cathode is commonly made up of a stable metal that is typically thermally deposited in vacuum onto the top surface of the low work function metal cathode. Useful metals for the passivation layer are known in the art and include, for example, Ag and Al and the like. The thickness of the passivation layer is not critical and can be adjusted to achieve the desired surface resistance (surface resistance or sheet resistance is defined as the resistivity divided by the thickness) and can vary in the range of from few hundred Angstroms to more than one thousand Angstroms.

The PLEDs comprising salts provided herein can be incorporated in any available display device, including a full color LED display, a cell phone display, a PDA (personal digital assistant), portable combination devices performing multiple functions (phone/PDA/camera/etc.), a flat panel display including a television or a monitor, a computer monitor, a laptop computer, a computer notepad, and an integrated computer-monitor systems. Such PLEDs may be incorporated in active or passive matrices.

### EXAMPLES

The following examples are set forth so as to provide those of ordinary skill in the art with a complete description of how to make and use the present invention, and are not intended to limit the scope of what is regarded as the invention. Efforts have been made to ensure accuracy with respect to numbers used (e.g., amounts, temperature, etc.) but some experimental error and deviation should be accounted for. Unless otherwise indicated, parts are parts by weight, temperature is degree centigrade and pressure is at or near atmospheric, and all materials are commercially available.

Experimental

The following examples illustrate certain embodiments of the invention.

Examples 1-12 describe the exchange procedure for cationic conjugated polymers and the characterization of the resulting materials.

General Details. All commercial chemical reagents were obtained from Aldrich and used as received. 1H NMR spectra were collected on a Varian Unity Inova 400 MHz spectrometer. UV-vis absorption spectra were recorded on a Shimadzu UV-2401 PC diode array spectrometer. Fluorescence was measured by using a PTI Quantum Master fluorometer. Gel permeation chromatography (GPC) measurements were done in a Waters GPC 2410 in tetrahydrofuran (THF) via a calibration curve of polystyrene standards. Dynamic light scattering (DLS) was recorded using 10 mW HeNe laser (wavelength 633 nm) with a photodiode detector BI-APD (Brookhaven Instruments Co.). The synthesis of PFBT-Br was adapted from the literature.

### Poly[9,9-bis(6′-bromohexyl)fluorene-alt-4,7-(2,1,3-benzothiadiazole)]

Carefully purified 2,7-bis(4,4,5,5-tetramethyl-1,3,2-dioxaborolan-2-yl)-9,9-bis(6′-bromohexyl)fluorene (0.5 mmol, 372 mg), 4,7-dibromo-2,1,3-benzothiadiazole (0.5 mmol, 147 mg) and Pd(PPh₃)₄ (10 mg) were dissolved in a mixture of toluene and aqueous 2 M Na₂C0₃. The solution was refluxed with vigorous stirring for 36 h under an argon atmosphere. The mixture was then poured into methanol. The precipitated material was recovered by filtration and washed for 3 h by stirring in acetone to remove oligomers and catalyst residues. The resulting solids were air-dried overnight, followed by drying under vacuum to afford PFBT precursor 224 mg (72%) as a bright yellow powder. GPC analysis gave Mn=22,500 and PDI=1.8. ¹H NMR (400 MHz, CDCl₃), δ (ppm): 8.10-7.68 (m, 8H), 3.28 (m, 4H), 2.10 (m, 4H), 1.68 (m, 4H), 1.30-1.12 (m, 8H), 0.89-0.75 (m, 4H).

### Poly[(9,9-bis(6′-N,N,N-trimethylammoniumbromide)hexyl)fluorene-alt-4,7-(2,1,3-benzothiadiazole)] (PFBT-Br)

Condensed trimethylamine (2.5 mL) was added dropwise to a solution of the neutral precursor polymer (100 mg) in tetrahydrofuran (10 mL) at −78° C. The mixture was allowed to warm up to room temperature gradually. The precipitate was redissolved by addition of excess water, and then an extra 2 mL trimethylamine was added at −78° C., and the mixture was stirred vigorous for 24 h at room temperature. After removal of most of the water under reduced pressure, acetone was added to precipitate the cationic polymer, which was collected and dried in a vacuum oven to give 101 mg (85%) of PFBT-Br as a powder. ¹H NMR (400 MHz, DMSO-d6), δ (ppm): 8.30-7.97 (m, 8H), 3.36 (m, 4H), 3.22 (br, 4H), 2.98 (s, 18H), 1.53 (br, 4H), 1.14 (br, 8H), 0.84 (br, 4H).

General Anion Exchange Procedure

### Poly[(9,9-bis(6′-N,N,N-trimethylammonium)hexyl)fluorene-alt-4,7-(2,1,3-benzothiadiazole)]X (PFBT-X)

56 mg PFBT-Br (0.075 mmol in repeat units) was dissolved in 10 mL methanol. Subsequently, a solution of the corresponding salt (0.45 mmol) in 10 mL water and/or methanol was added. The mixture was stirred for two days at room temperature. After removal of methanol under reduced pressure, deionized water was added several times to wash the residue. The overall procedure can be repeated until the majority of the bromide is removed. Finally, the resulting polymer was dried under vacuum. X-ray photoelectron spectroscopy (XPS), NMR and elemental analysis were used to characterize the polyelectrolytes with exchanged anions.

X-Ray Photoelectron Spectroscopy Analysis

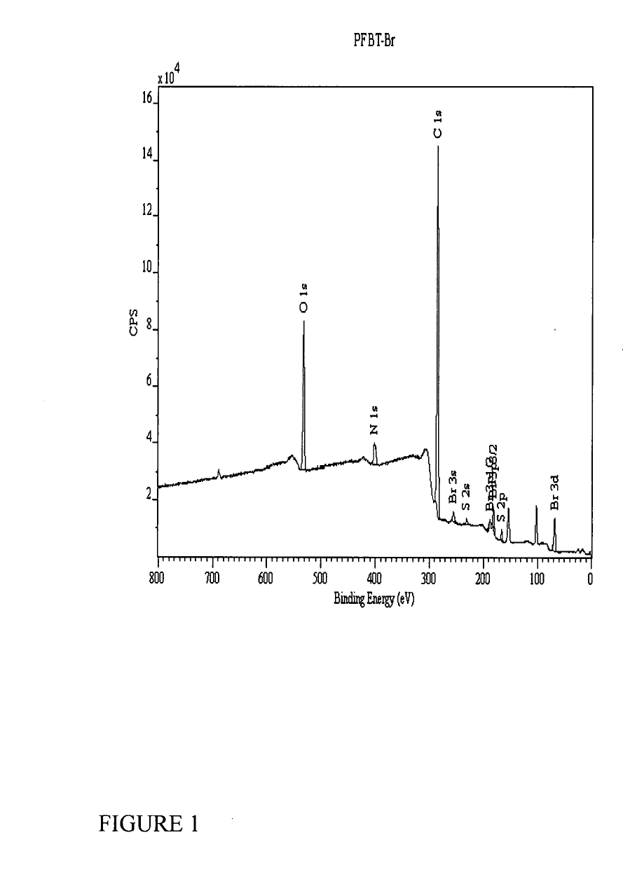

XPS spectra were recorded on Kratos Axis Ultra XPS system with a base pressure of 1×10⁻¹⁰ mbar (UHV), using a monochromated Al Kα X-ray source at hv=1486 eV. Polymer samples were placed on one side of a double-sided carbon adhesive. The measured binding energy (BE) of C1s was referenced to 284.5 eV. The two peaks located at binding energy about 99 and 149 eV assigned to Si2p and Si2s of the carbon adhesive. When the sample film was thinner, the two peaks of Si element were higher. The original polymer containing Br anion (PFBT-Br) showed 4 distinct characteristic peaks of Br atom (FIG. 1). Br3d, Br3p_{3/2}, Br3p_{1/2} and Br3s located at binding energy of 69 eV, 182 eV, 189 eV and 257 eV, respectively. The peak at 532 eV of O1s originated from water in polymer. In the XPS spectra of polyelectrolyte exchanged Br with different anions, the Br peaks nearly disappeared, and the corresponding exchange ions' elemental characteristic peaks were recorded. For PFBT-BF₄, the F1s and F2s located at 686 eV and 30 eV, respectively, and the B1s peak appeared at 192 eV, a little higher than normal value because of fluoro atoms around of boron. For PFBT-CF₃SO₃, F1s appeared at 687 eV, and S2p has four peaks (163, 164, 166, and 167 eV), corresponding to two different chemical environments of sulfur atoms. For PFBT-PF₆, F1s, F2s and P2p located at 686, 31 and 135 eV, respectively. For PFBT-BPh₄, B1s appeared at 187 eV. For BAr^{F}₄, F1s, F2s and B1s located at 687, 31 and 188 eV, respectively. Atomic concentration ratios calculated from peak intensities using CasaXPS Version 2.3.5 software revealed greater than 95% bromide exchange.

Scanning probe measurements. All measurements were done under ambient conditions and in the dark using a commercial scanning probe microscope (MultiMode equipped with CAFM module and the Nanoscope Controller IIIa, Veeco Inc.). Platinum-coated Si tips with spring constant of 0.2 N/m and the tip radius of 25 nm were used (Budget Sensors). In these measurements, the conducting probe makes contact with the sample (the tip acts as a nanoelectrode) and measures current as a function of applied voltage either at certain points on a surface (I-V curve) or map out a current image at a fixed bias. The bias was applied to the conducting substrate and the current was measured by a preamplifier. For each sample, the I-V curves and topographic Images were collected on multiple locations to examine the film uniformity.

Polymer films were cast onto an ITO-coated glass substrate from methanol solutions (3.42×10⁻³ M in polymer repeat units). The film thickness was 18 nm for PFBT-Br and 20 nm for PFBT-BAr^{F}₄ as measured by ellipsometry and by AFM. Subsequently the probe tip was used to measure current across the film with a tip-sample contact area of ˜114 nm² using the Hertz model². The bias was applied to the conducting substrate. The same tip and applied contact force (40 nN) were used to obtain the I-V curves for all samples to ensure identical contact resistance. To test the tip quality, the I-V curves of the ITO or gold substrate were collected before and after the I-V curves at each location were measured. The data and the tip were discarded whenever the current decreased—a sign of a damaged or worn tip. To prolong tip lifetime, samples were imaged in tapping mode, then I-V curves were collected at selected points in contact mode.

Analysis of C-AFM Data: It is well-accepted that the charge transport for most conjugated polymers is dominated by a thermally activated hopping mechanism in which carriers hop across barriers created by the presence of isolated states or domains. The space charge limiting current (SCLC) conduction model can often be used to describe the current-voltage characteristics of electrons or holes in these materials due to the low the charge carrier mobility. Under these conditions, the current density, J, can be described by the trap-free Mott-Gurney law:

$$J = \frac{9}{8} {ɛ}_{r} {ɛ}_{o} μ \frac{{V}^{2}}{{L}^{3}} \qquad ( 1 )$$

where εᵣ is the dielectric constant of the polymer, εₒ is the vacuum permittivity, μ is the charge mobility, V is the applied voltage, and L is the film thickness. When the current-voltage follows a square-law dependence the charge process is thus trap-free space charge limited. If the current-voltage follows a power-law dependence (I˜V^{m} with m>2), the charge transport process is trap-dependent. Generally, a transition from J˜V¹ (ohmic) at low voltages to J˜V² (space-charge-limited) to J˜V^{m}, m>2 (trapped filling) at high voltages indicates the presence of shallow traps whereas a direct transition from J˜V¹ to J˜V^{m} indicates the presence of deep traps. SCLC in the presence of single discrete energy level traps is described by:

$$J = \frac{9}{8} {ɛ}_{r} {ɛ}_{o} θμ \frac{{V}^{2}}{{L}^{3}} \\ With \\ θ = \frac{n}{n + {n}_{t}} \\ or \\ θ = \frac{p}{p + {p}_{t}} \qquad ( 2 )$$

for electron and hole, respectively. In Equation 2, n is the density of free electrons, n₁ is the density of trapped electrons, p is the density of free holes, and p₁ is the density of trapped holes. Experimentally, θ is determined from the ratio of J at the beginning and at the end of the J˜V² region: θ=Jₘᵢₙ/Jₘₐₓ. For Equation 2 to apply, the charge mobility has to be independent, or weakly dependent, on the electric field.

The following reaction Scheme A is referred to in Examples 1-7. Scheme A

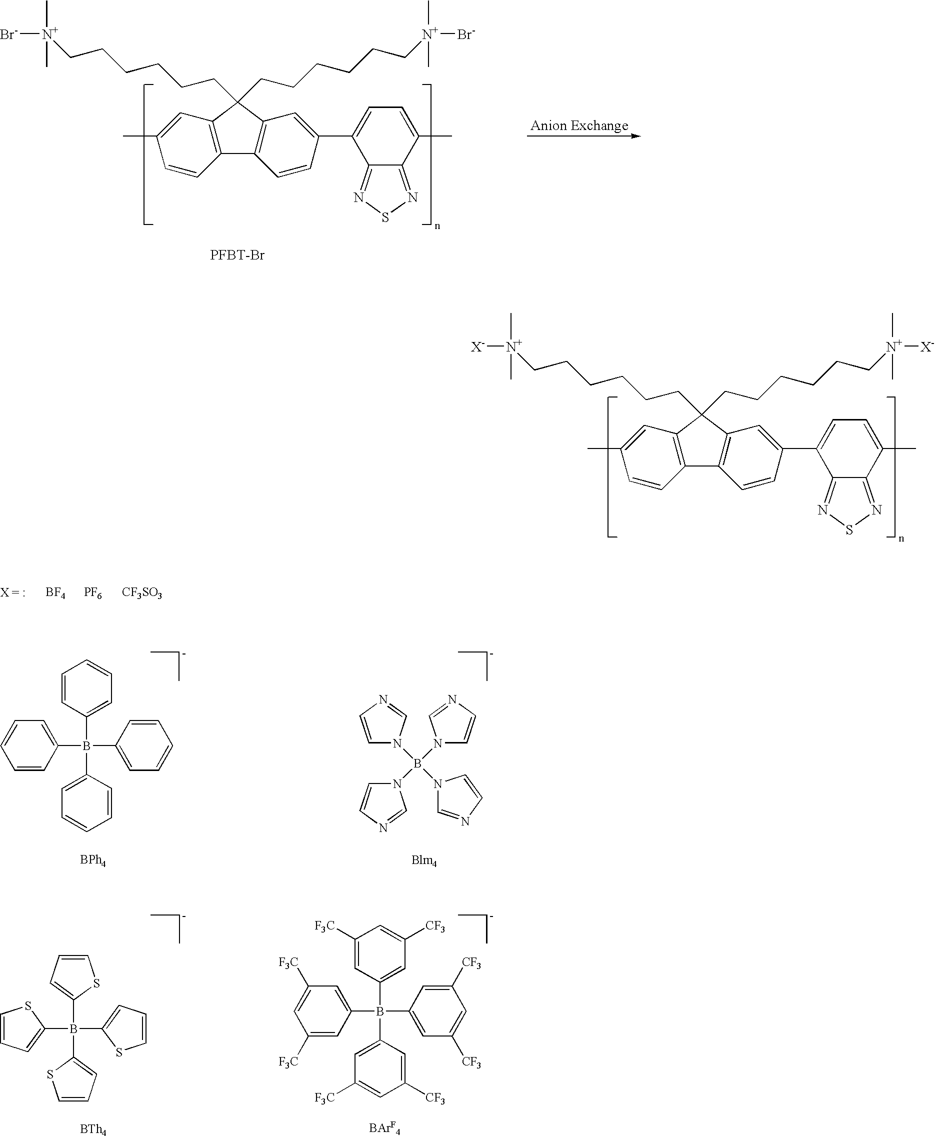

In Examples 1-7, the anion is given in bold and corresponds to Scheme A.

### Example 1

### Poly[(9,9-bis(6′-N,N,N-trimethylammonium)hexyl)fluorene-alt-4,7-(2,1,3-benzothiadiazole)]tetrafluoroborate (PFBT-BF₄)

The original polymer PFBT-Br 56 mg (0.075 mmol) and sodium tetrafluorohorate 50 mg (0.45 mmol) were used to provide 39 mg (69%) of PFBT-BF₄. ¹H NMR (400 MHz, DMSO-d6). δ (ppm): 8.28-7.94 (m, 8H), 3.36 (m, 4H), 3.12 (br, 4H), 2.93 (s, 18H), 1.48 (br, 4H), 1.16-1.05 (m, 8H), 0.78 (br, 4H). Anal. Calcd: C, 58.73; H, 6.61; N, 7.41. Found: C, 55.51; H, 5.86; N, 6.67.

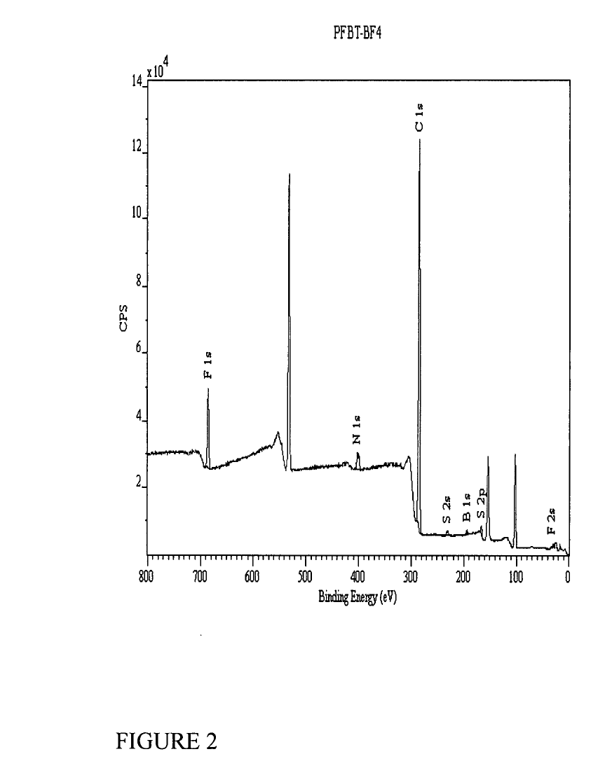

Greater than 95% bromide exchange was confirmed by XPS analysis of PFBT powders (Example 1 to 7). The parent PFBT-Br displays 4 peaks characteristic of Br⁻ (Br3d, Br3p_{3/2}, Br3p_{1/2} and Br3s at binding energies (BE) of 69 eV, 182 eV, 189 eV and 257 eV, respectively) (FIG. 1). In the XPS spectra of polyelectrolyte exchanged Br⁻ with different anions, the Br⁻ peaks nearly disappeared, and peaks corresponding to the exchange ions are recorded. In the case of PFBT-BF₄, the F1s and F2s located at 686 eV and 30 eV, respectively, and the B1s peak appeared at 192 eV, a little higher than normal value because of fluorine atoms around of boron (FIG. 2).

### Example 2

### Poly[(9,9-bis(6′-N,N,N-trimethylammonium)hexyl)fluorene-alt-4,7-(2,1,3-benzothiadiazole)]hexafluorophosphate (PFBT-PF₆)

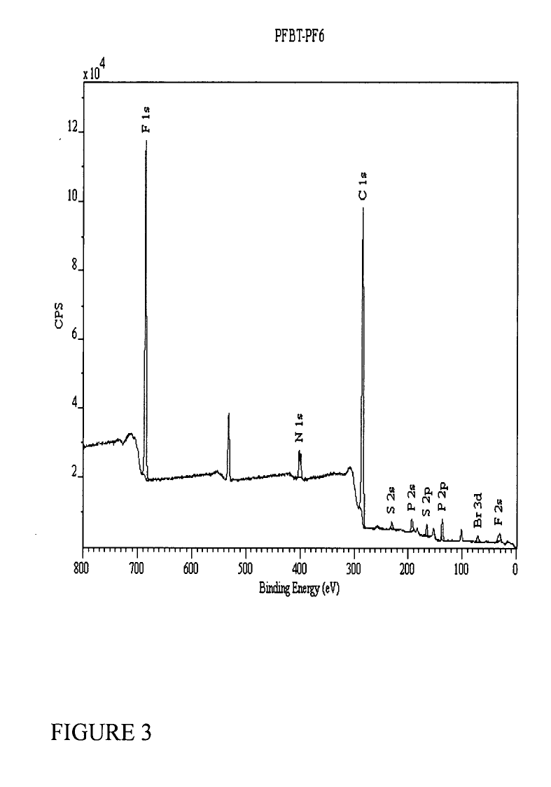

PFBT-Br 56 mg (0.075 mmol) and ammonium hexafluorophosphate 73 mg (0.45 mmol) were used to provide 49 mg (75%) of PFBT-PF₆. ¹H NMR (400 MHz, DMSO-d6). δ (ppm): 8.25-7.82 (m, 8H), 3.37 (m, 4H), 3.12 (br, 4H), 2.93 (s, 18H), 1.50 (br, 4H), 1.14 (br, 8H), 0.81 (br, 4H). Anal. Calcd: C, 50.92; H, 5.73; N, 6.42. Found: C, 50.67; H, 5.22; N, 5.72. XPS spectra, F1s, F2s and P2p located at 686, 31 and 135 eV, respectively (FIG. 3).

### Example 3

### Poly[(9,9-bis(6′-N,N,N-trimethylammonium)hexyl)fluorene-alt-4,7-(2,1,3-benzothiadiazole)]trifluoromethanesulfonate (PFBT-CF₂S0₃)

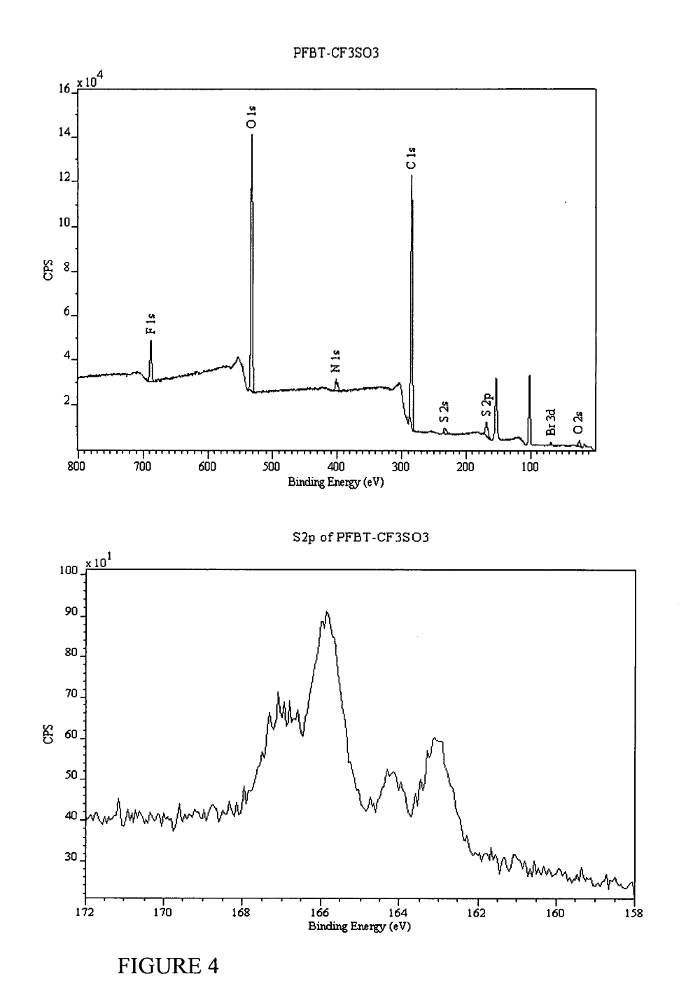

PFBT-Br 56 mg (0.075 mmol) and sodium trifluoromethanesulfonate 77 mg (0.45 mmol) were used to provide 47 mg (71%) of PFBT-CF₃S0₃. ¹H NMR (400 MHz, DMSO-d6). δ (ppm): 8.30-7.90 (m, 8H), 3.34 (m, 4H), 3.11 (br, 4H), 2.93 (s, 18H), 1.50 (br, 4H), 1.14 (br, 8H), 0.82 (br, 4H). Anal. Calcd: C, 53.18; H, 5.68; N, 6.36. Found: C, 49.93; H, 5.43; N, 5.61. XPS spectra, F1s appeared at 687 eV, and S2p has four peaks (163, 164, 166, and 167 eV), corresponding to two different chemical environments of sulfur atoms (FIG. 4).

### Example 4

### Poly[(9,9-bis(6′-N,N,N-trimethylammonium)hexyl)fluorene-alt-4,7-(2,1,3-benzothiadiazole)]tetraphenylborate (PFBT-BPh₄)

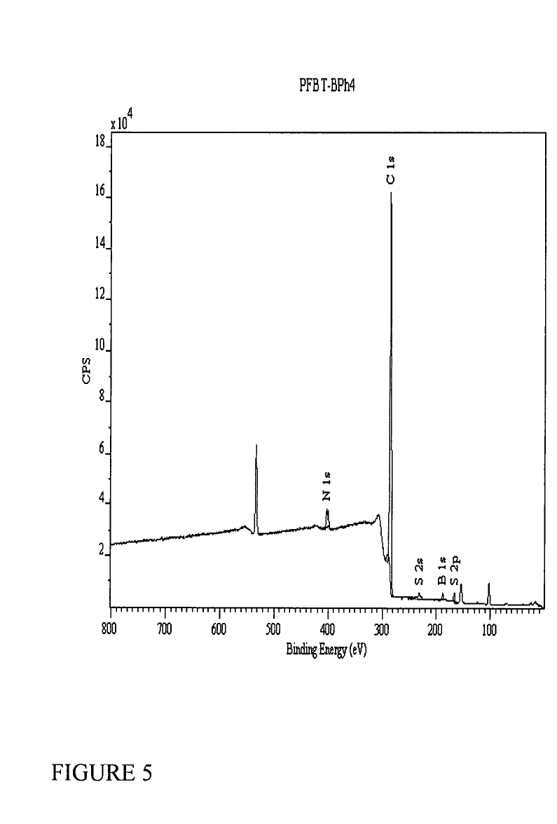

PFBT-Br 56 mg (0.075 mmol) and ammonium tetraphenylborate 152 mg (0.45 mmol) were used to provide 67 mg (73%) of PFBT-BPh₄. ¹H NMR (400 MHz, DMSO-d6). δ (ppm): 8.25-7.92 (m, 8H), 7.18 (s, 16H), 6.91 (t, 16H, J=7.2 Hz), 6.77 (t, 8H, J=7.2 Hz), 3.36 (m, 4H), 3.07 (br, 4H), 2.87 (s, 18H), 1.45 (br, 4H), 1.15 (br, 8H), 0.83 (br, 4H). Anal. Calcd: C, 83.61; H. 7.38; N, 4.59. Found: C, 77.19; H, 7.11; N, 4.55. XPS spectra, B1s appeared at 187 eV (FIG. 5).

### Example 5

### Poly[(9,9-bis(6′-N,N,N-trimethylammonium)hexyl)fluorene-alt-4,7-(2,1,3-benzothiadiazole)]tetrakis(1-imidazolyl)borate (PFBT-BIm₄)

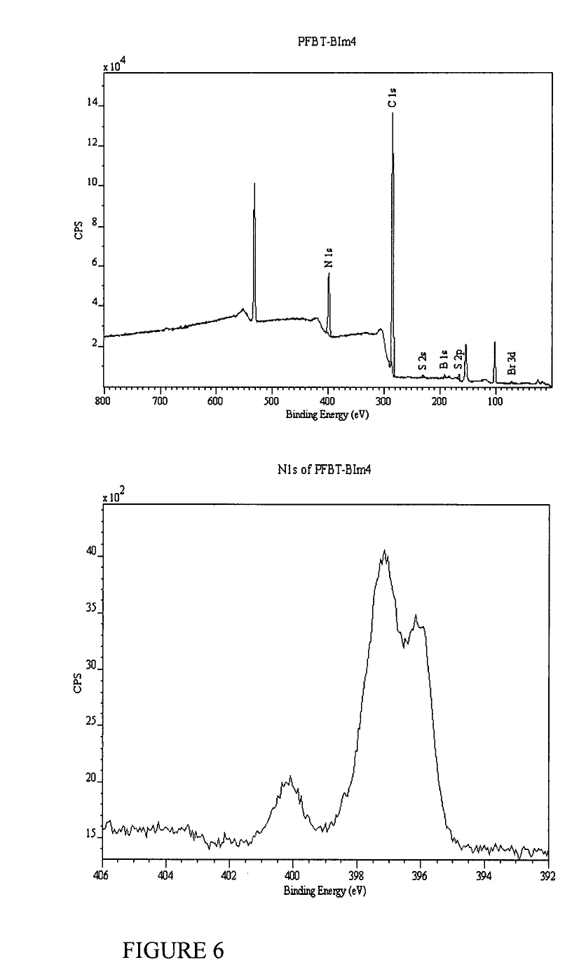

PFBT-Br 56 mg (0.075 mmol) and sodium tetrakis(1-imidazolyl)borate 136 mg (0.45 mmol) were used to provide 53 mg (62%) of PFBT-BIm₄. ¹H NMR (400 MHz, DMSO-d6). δ (ppm): 8.26-7.90 (m, 8H), 7.10 (s, 8H), 6.96 (s, 8H), 6.79 (s, 8H), 3.40 (m, 4H), 3.12 (br, 4H), 2.94 (s, 18H), 1.47 (br, 4H), 1.11 (br, 8H), 0.77 (br, 4H). Anal. Calcd: C, 64.21; H, 6.49; N, 24.56. Found: C, 55.89; H, 5.79; N, 21.44. XPS spectra, B1s appeared at 190 eV, and N1s was split into three peaks (400, 397, and 396 eV), corresponding to three different chemical environments of nitrogen atoms (FIG. 6).

### Example 6

### Poly[(9,9-bis(6′-N,N,N-trimethylammonium)hexyl)fluorene-alt-4,7-(2,1,3-benzothiadiazole)]tetrakis(2-thienyl)borate (PFBT-BTh₄)

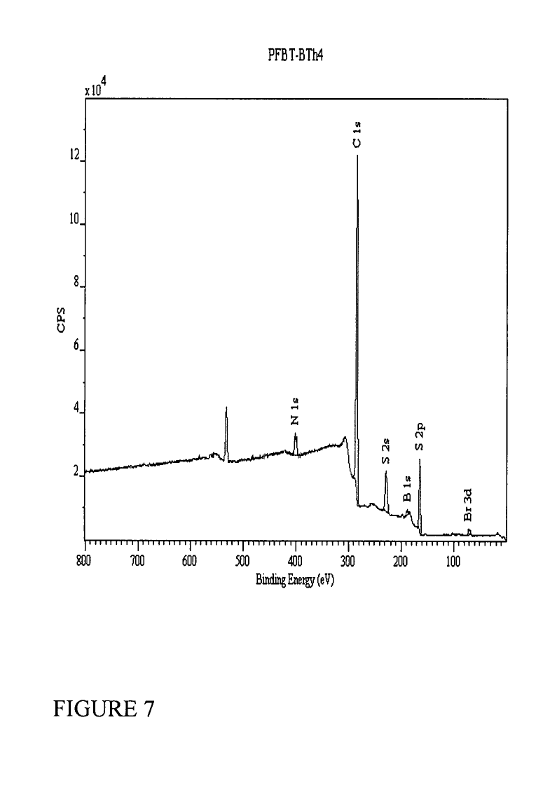

PFBT-Br 56 mg (0.075 mmol) and potassium tetrakis(2-thienyl)borate 172 mg (0.45 mmol) were used to provide 62 mg (65%) of PFBT-BTh₄. ¹H NMR (400 MHz, DMSO-d6). δ (ppm): 8.24-7.89 (m, 8H), 7.11 (d, 8H), 6.83 (t, 8H, J=3.6 Hz), 6.72 (s, 8H), 3.37 (m, 4H), 3.06 (br, 4H), 2.87 (s, 18H), 1.45 (br, 4H), 1.14 (br, 8H), 0.80 (br, 4H). Anal. Calcd: C, 65.30; H, 5.83; N, 4.42. Found: C, 61.79; H, 5.52; N, 3.91. XPS spectra, B1s appeared at 188 eV, S2s and S2p located at 229 and 164 eV, respectively (FIG. 7).

### Example 7

### Poly[(9,9-bis(6′-N,N,N-trimethylammonium)hexyl)fluorene-alt-4,7-(2,1,3-benzothiadiazole)]tetrakis[3,5-bis(trifluoromethyl)phenyl]borate (PFBT-BAr^{F}₄)

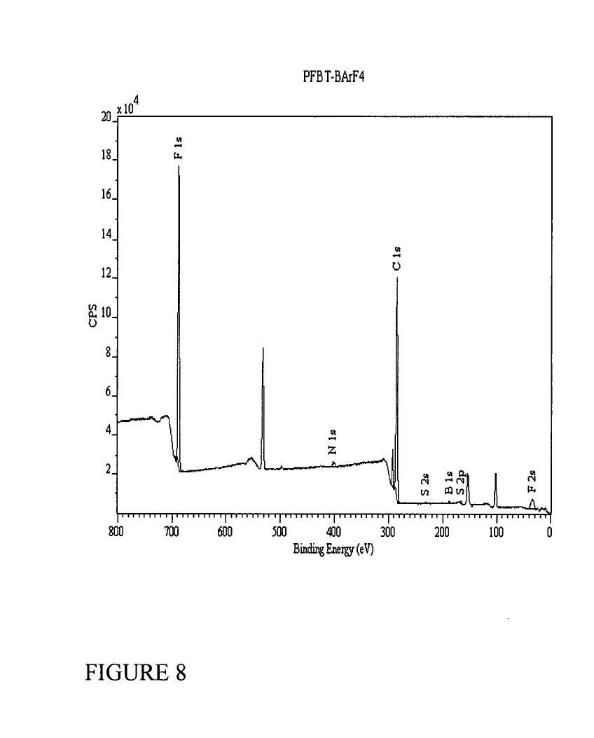

PFBT-Br 19 mg (0.026 mmol) and sodium tetrakis[3,5 [symbol] bis(trifluoromethyl)phenyl]borate 50 mg (0.056 mmol) were used to provide 44 mg (73%) of PFBT-BAr^{F}₄, ¹H NMR (400 MHz, DMSO-d6). δ (ppm): 8.27-7.98 (m, 8H), 7.70 (s, 8H), 7.61 (s, 16H), 3.36 (m, 4H), 3.12 (br, 4H), 2.93 (s, 18H), 1.47 (br, 4H), 1.13 (br, 8H), 0.84 (br, 4H). Anal. Calcd: C, 52.51; H, 3.21; N, 2.43. Found: C, 49.13; H, 2.98; N, 2.08. XPS spectra, F1s, F2s and B1s located at 687, 31 and 188 eV, respectively (FIG. 8).

The following reaction Scheme B is referred to Examples 8-10. Scheme B

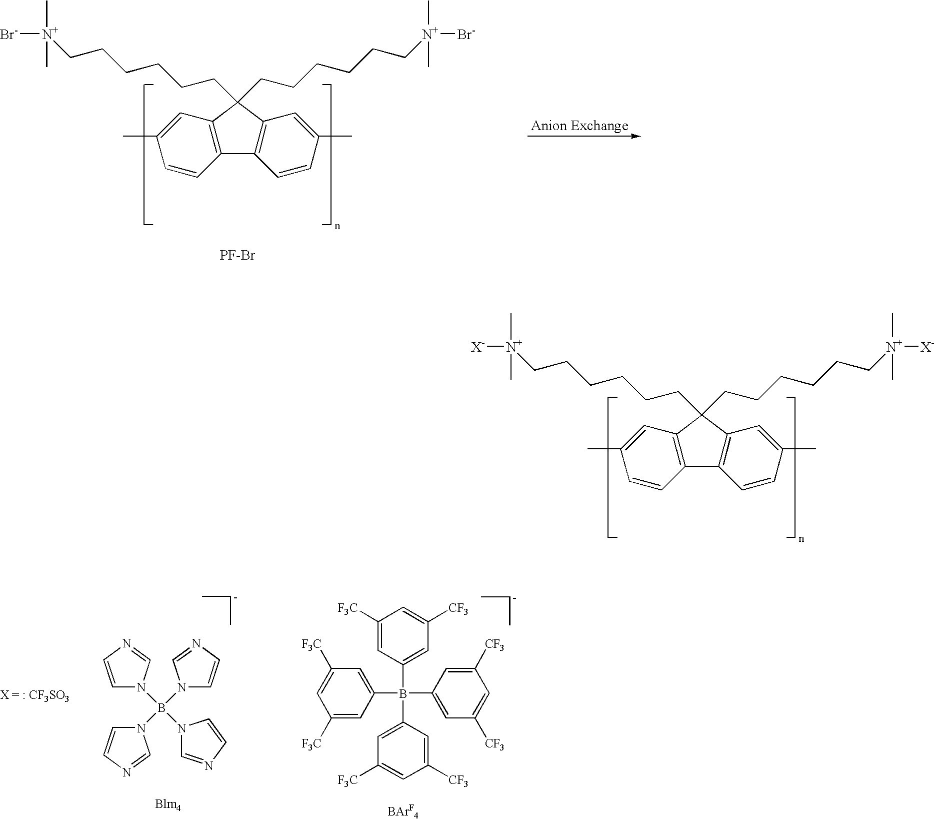

### Example 8

### Poly[(9,9-bis(6′-N,N,N-trimethylammonium)hexyl)fluorene]trifluoromethanesulfonate (PF-CF₃S0₃)

PF-Br 46 mg (0.075 mmol) and sodium trifluoromethanesulfonate 77 mg (0.45 mmol) were used to provide 41 mg (74%) of PF-CF₃S0₃. ¹H NMR (400 MHz, DMSO-d6). δ (ppm): 8.27-7.92 (m, 6H), 3.33 (m, 4H), 3.15 (br, 4H), 2.95 (s, 18H), 1.50 (br, 4H), 1.13 (br, 8H), 0.83 (br, 4H).

### Example 9

### Poly[(9,9-bis(6′-N,N,N-trimethylammonium)hexyl)fluorene]tetrakis(1-imidazolyl)borate (PF-BIm₄)

PF-Br 46 mg (0.075 mmol) and sodium tetrakis(1-imidazolyl)borate 136 mg (0.45 mmol) were used to obtain 49 mg (65%) of PF-BIm₄. ¹H NMR (400 MHz, DMSO-d6). δ (ppm): 8.26-7.93 (m, 6H), 7.11 (s, 8H), 6.94 (s, 8H), 6.77 (s, 8H), 3.38 (m, 4H), 3.10 (br, 4H), 2.96 (s, 18H), 1.45 (br, 4H), 1.13 (br, 8H), 0.80 (br, 4H).

### Example 10

### Poly[(9,9-bis(6′-N,N,N-trimethylammonium)hexyl)fluorene]tetrakis[3,5-bis(trifluoromethyl)phenyl]borate (PF-BAr^{F}₄)

PF-Br 16 mg (0.026 mmol) and sodium tetrakis[3,5-bis(trifluoromethyl)phenyl]borate 50 mg (0.056 mmol) were used to obtain 42 mg (75%) of PF-BAr^{F}₄. ¹H NMR (400 MHz, DMSO-d6). δ (ppm): 8.24-7.97 (m, 6H), 7.72 (s, 8H), 7.59 (s, 16H), 3.34 (m, 4H), 3.13 (br, 4H), 2.95 (s, 18H), 1.47 (br, 4H), 1.14 (br, 8H), 0.82 (br, 4H).

### Example 11

### Poly[(9,9-bis(6′-N,N,N-trimethylammonium)hexyl)fluorene-alt-1,4-phenyl)]tetrakis(pentafluorophenyl)borate (PFB-BPh^{F}₄)

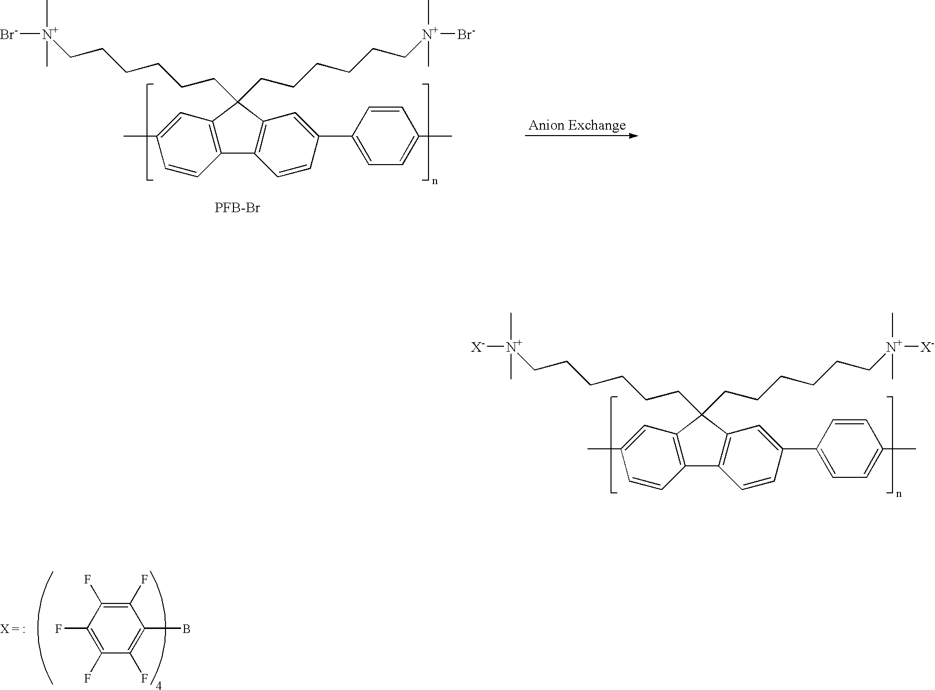

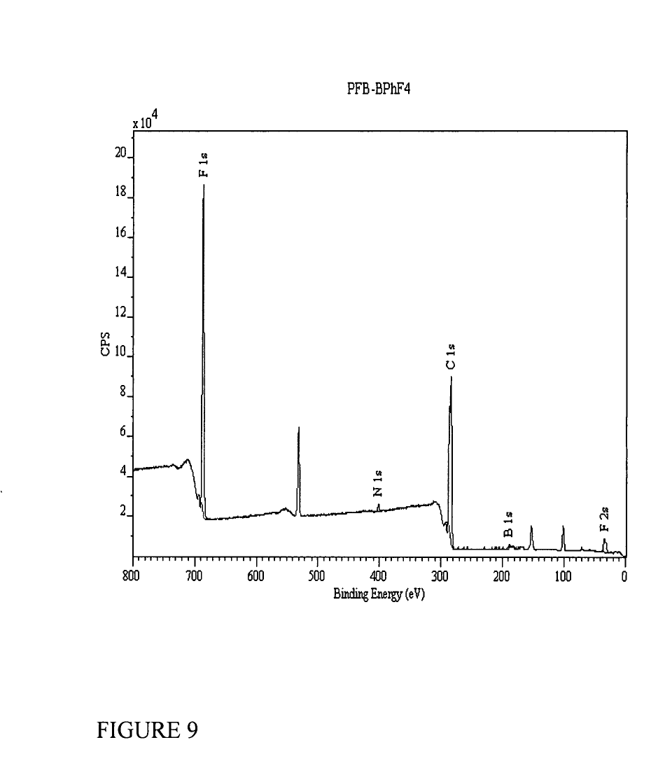

PFB-Br 51 mg (0.075 mmol) and lithium tetrakis(pentafluorophenyl)borate 308 mg (0.45 mmol) were used to obtain 94 mg (67%) of PFB-BPh^{F}₄. ¹H NMR (400 MHz, DMSO-d6). δ (ppm): 8.29-7.79 (m, 10H), 3.33 (m, 4H), 3.10 (br, 4H), 2.85 (s, 18H), 1.44 (br, 4H), 1.13 (br, 8H), 0.81 (br, 4H). XPS spectra, F1s, F2s and B1s located at 686, 31 and 188 eV, respectively (FIG. 9).

### Example 12

### Poly[(9,9-bis(6′-N,N,N-trimethylammonium)hexyl)fluorene-alt-4,4-((N-4′-(6″-N,N,N-trimethylammonium)hexyl)phenyl)diphenylamine]trifluoromethanesulfonate (PFTPA-CF₃S0₃)

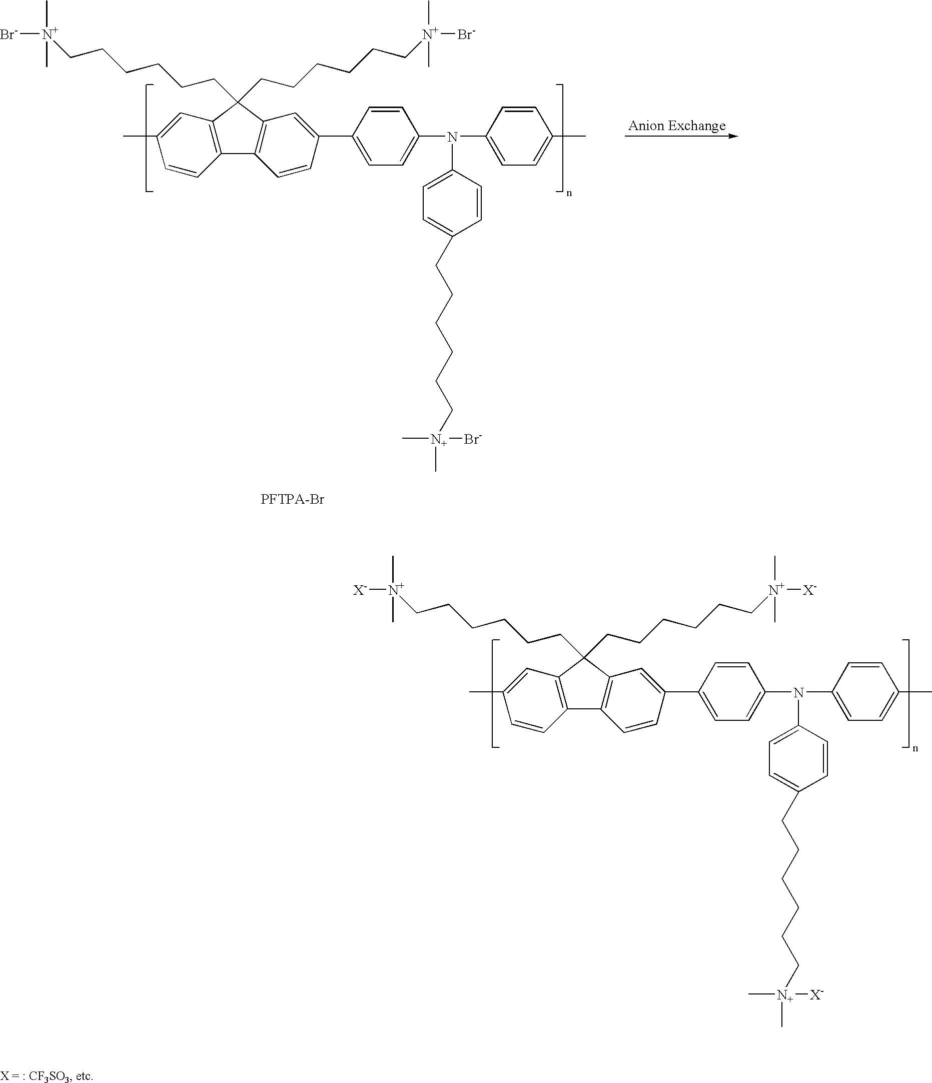

PFTPA-Br 80 mg (0.075 mmol) and sodium trifluoromethanesulfonate 117 mg (0.68 mmol) were used to obtain 61 mg (64%) of PFTPA-CF₃SO₃.

### Example 13

### Absorption and Photoluminescence Properties

Absorption and PL spectra of PFBT with different CAs in dimethylsulfoxide (DMSO), methanol, deionized water and in the solid state are summarized in the Table A. Measurements in DMSO as a function of CA provide the least variations in the range of the absorption maxima (λabs˜450-455 nm; Δλₘₐₓ=5 nm) and PL maxima (λ_{PL}˜569-572 nm; Δλ_{PL}=3 nm). PL quantum yields (Φs), determined by comparison with emission standards in the same solvent, range from 35% (Br) to 45% (BAr^{F}₄). These values are quite similar, given the statistical uncertainties that arise from errors in Φ determination (±5%). The CAs make a more substantial influence on the absorbance and emission properties in water, relative to DMSO, as shown by the larger values of Δλ_{abs} (14 nm) and Δλ_{PL} (20 nm) and the larger Φ range, from 3% (Br) to 22% (BAr^{F}₄). In methanol, the changes in optical properties as a function of CA more closely resemble those in DMSO than in water and are provided in Table A for comparison with the properties measured in films spun cast from methanol. Finally, similar trends to those observed in water occur in the films, with Δλ_{abs}=18 nm and Δλ_{PL}=18 nm. More pronounced changes occur in the Φs of the films, where values span from 5% (Br) to 41% (BAr^{F}₄). These solid state measurements involved examination of films spun from methanol, optical excitation at 364 nm and collection of emission using an integrating sphere. That the data in water and in the solid show similar trends is consistent with significant aggregation in solution as a result of the hydrophobic nature of the π-delocalized backbone and thereby emission self-quenching by interchain coupling.

TABLE A
Summary of absorption and PL spectra and Φ of PFBT-CA solutions
and films.

| | DMSO | | | MeOH | | | H₂O | | | Film^{a} | | |
|---|---|---|---|---|---|---|---|---|---|---|---|---|
| | UV | PL | | UV | PL | | UV | PL | | UV | PL | |
| | λ_{abs} | λ_{PL} | Φ | λ_{abs} | λ_{PL} | Φ | λ_{abs} | λ_{PL} | Φ | λ_{abs} | λ_{PL} | Φ |
| CA | (nm) | (nm) | (%) | (nm) | (nm) | (%) | (nm) | (nm) | (%) | (nm) | (nm) | (%) |
| Br | 450 | 570 | 35 | 446 | 568 | 29 | 435 | 589 | 3 | 467 | 574 | 5 |
| BF₄ | 454 | 572 | 39 | 444 | 562 | 31 | 441 | 592 | 4 | 449 | 570 | 8 |
| CF₃SO₃ | 455 | 572 | 43 | 451 | 565 | 34 | 442 | 576 | 5 | 463 | 578 | 12 |
| PF₆ | 450 | 572 | 43 | 443 | 564 | 29 | 439 | 588 | 6 | 449 | 574 | 11 |
| BIm₄ | 451 | 569 | 38 | 445 | 567 | 30 | 438 | 584 | 6 | 463 | 571 | 10 |
| BPh₄ | 451 | 569 | 34 | 449 | 568 | 28 | 446 | 577 | 9 | 460 | 570 | 15 |
| BAr^{F}₄ | 455 | 570 | 45 | 450 | 563 | 36 | 449 | 572 | 22 | 457 | 560 | 41 |

^{a}Films were spun cast from MeOH solutions.

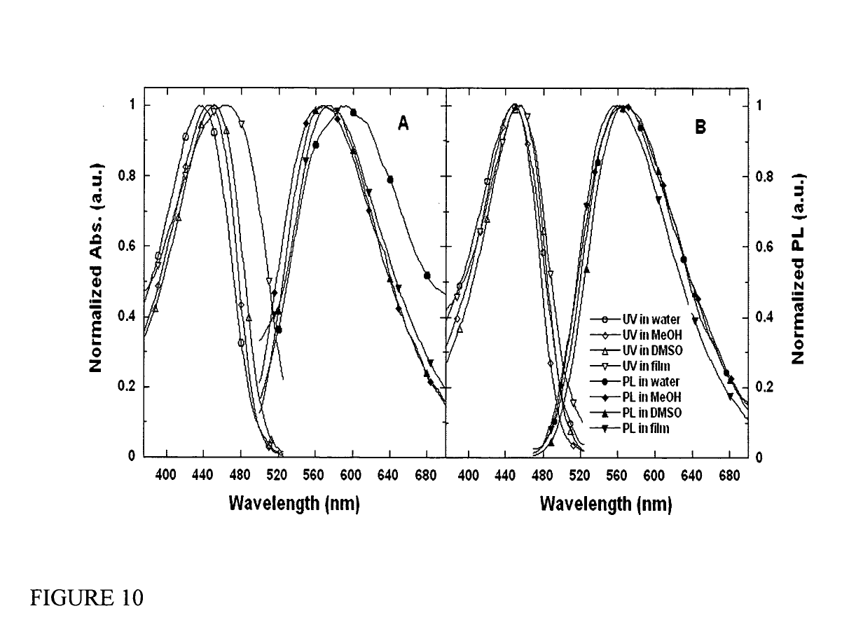

It is informative to examine the spectral features observed with the two CAs (Br⁻ and BAr^{F}₄⁻) that give rise to the largest difference in Φ values (FIG. 10). Focusing on the film spectra, one observes that the absorption spectrum is considerably broader for PFBT-Br, relative to PFBT-BAr^{F}₄. We suggest that the smaller size of Br⁻ allows for more intimate interchain contacts, a broader distribution of sites and increased self-quenching. Consistent with this proposal is that the solid state Φ values in Table A roughly track with the CA size, with the largest anions providing more efficient emission. In the aqueous aggregates, where interchain contacts are known to lead to PL self-quenching, a similar phenomenon can be invoked, with the larger CAs providing “spacers” that separate more effectively the polymer chains.

Comparison of the absorbance and PL peak shapes of PFBT-Br and PFBT-BAr^{F}₄ shows that the presence of the larger BAr^{F}₄⁻ anion also makes the spectra less sensitive to perturbations from the environment (FIG. 10). Interestingly, this lack of sensitivity to the solvent suggests that most spectral changes are induced by interchain contacts, rather than medium polarity and/or hydrogen bonding ability (in the case of the films, the polymer itself behaves as the solvent). This behavior is somewhat unexpected in view of electronic structure calculations for the uncharged analog of PFBT, which indicate a LUMO localized on the BT units and a charge redistribution upon excitation; features that should give rise to solvatochromism.

### Example 14

### Aggregation in Solution

As described previously, the coil conformation and the aggregation of conjugated polymers in solution are often reflected in the distribution of chains in spun-cast films. The presence of aggregates in conjugated polymers has been studied extensively and is known to increase fluorescence quenching and facilitate interchain charge transfer and thus charge mobility in the solid. For CPs in a polar medium, the chains presumably come together and aggregate to minimize exposure of the hydrophobic π-conjugated backbone. Even in the case of well-defined charged oligomers, one obtains aggregates that incorporate hundreds of molecules, even at low concentrations.

With the considerations described in the preceding paragraph in mind, dynamic light scattering experiments were performed with the CAs that provide for the largest changes of the optical properties shown above. These studies in water, carried out over the concentration range of 1.2×10⁻⁵ M to 6.3×10⁻⁶ M, gave effective diameters of 353 nm for PFBT-Br and 73 nm for PFBT-BAr^{F}₄. Considering the increase in the mass of the repeat unit from Br⁻ (742 g/mol) to BAr^{F}₄⁻ (2308 g/mol) one would naturally expect larger dimensions for isolated chains. A comparison of the greater than three-fold anticipated molecular weight increase to the decrease in particle size obtained by light scattering provides strong support for invoking reduced aggregation for PFBT-BAr^{F}₄, relative to PFBT-Br. One possible explanation is that electrostatic association of the large BAr^{F}₄⁻ with the backbone inhibits contacts with other chains. Another factor to consider is that interactions of the chain with BAr^{F}₄, with its four aromatic units, may result in backbone-CA hydrophobic interactions that are not possible with Br⁻. Thus, the driving force for polymer chain packing to minimize contact with the aqueous surroundings is reduced.

### Example 15

### Charge Transport Properties

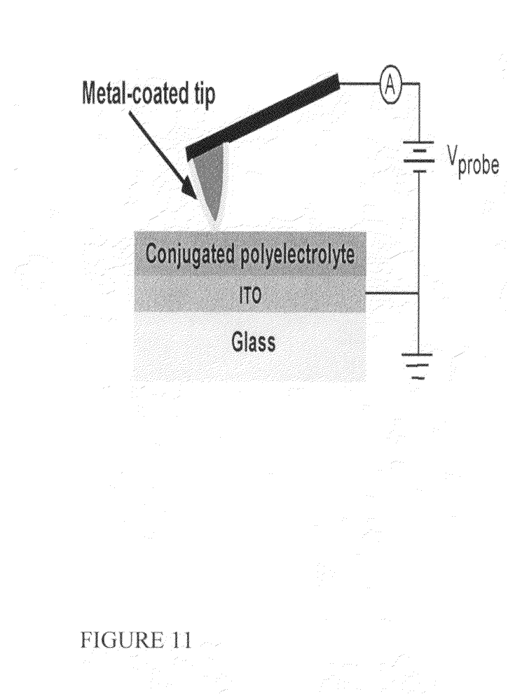

Atomic force microscopy (AFM) and conducting AFM (C-AFM) were used to examine local surface and electronic properties. C-AFM is a scanning probe technique, which can examine surface topography and local current simultaneously and can provide information on how CAs influence nanoscale charge transport properties. In these measurements, the conducting probe makes contact at different locations of the sample and a tip acts as a nanoelectrode to measure current as a function of applied voltage. One thus can obtain I-V curves at different sample locations to examine charge transport heterogeneity at the local level. FIG. 11 illustrates the test configuration used in our studies. The current measured is expected to be predominantly by hole transport, since the ITO substrate and the Pt tip have high work functions of 4.7 eV and 5.6 eV, respectively, and the polymer HOMO energy is approximately 5.8 eV. Based on consideration of these energies, there is a smaller barrier for hole injection from the Pt tip (˜0.2 eV) than from ITO (1.1 eV).

The effect of CAs on the surface roughness can be determined by AFM analysis. The thickness of films spun cast from methanol solutions are about 20 nm, a typical thickness of the electron transport layers used in multilayer polymer LEDs. The films are smooth and homogenous, with a rms roughness of 0.4 nm for PFBT-Br. In the case of PFBT-BAr^{F}₄, one observes circular topographic features with a diameter of ˜100 nm and a slightly increased roughness. These topographic features do not influence the charge mobility. To obtain smooth PFBT-BAr^{F}₄ films, one needs to stir the polymer in methanol for extended periods of time, typically at least four, eight or 12 hours, conveniently overnight. Shorter times lead to films with surfaces with more pronounced roughness.

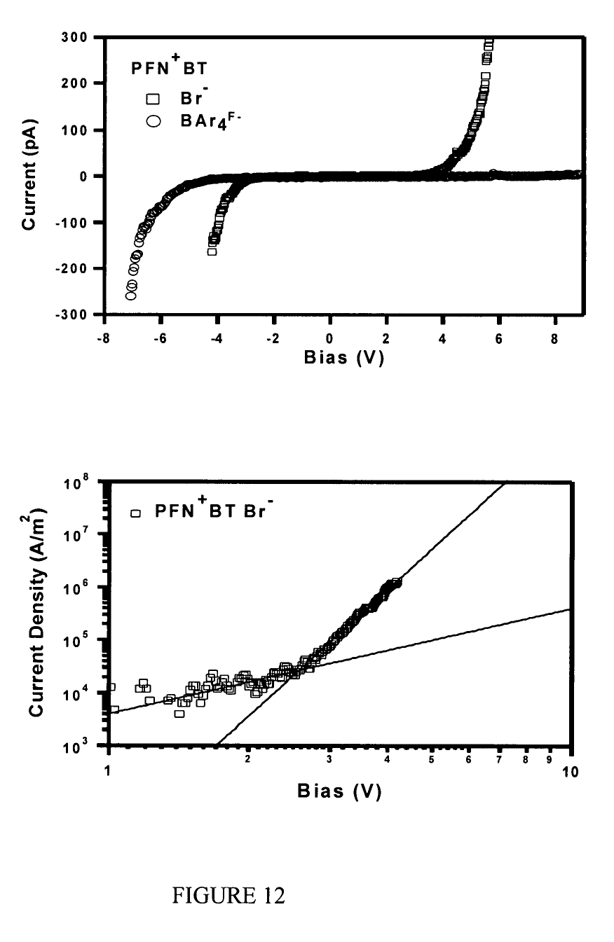

Representative I-V curves obtained by using the C-AFM technique are shown in FIG. 12a. In these measurements the tip/sample contact surface area is ˜114 nm². The data were collected from five sets of samples with forty I-V curves obtained from each sample. For the PFBT-Br film, current is observed in both reverse (holes are injected from the ITO) and forward bias (holes are injected from Pt tip), whereas for the PFBT-BAr^{F}₄ film, current is observed only in the forward bias. Furthermore, there are only minor statistical deviations in the currents measured in PFBT-BAr^{F}₄ films among the forty I-V curves collected at different locations. In the case of PFBT-Br one observes similar turn-on bias at all sites, however the I-V curves and maximum current fall within three different regimes, depending on the location of the film (Table B). These results indicate that morphologies with different chain packing arrangements are likely to be present in the PFBT-Br films.

Table B. Summary of maximum currents and hole mobilities for PFBT-Br and PFBT-BAr^{F}₄.

| CA | Current (pA) | Mobility (cm²/V · s.) |
|---|---|---|
| | At −7.2 V | |
| BAr^{F}₄ (forward bias) | 219 ± 28 | 9.4 × 10⁻⁶ |
| | At −4.2 V | |
| Br (forward bias) | 60.7 ± 12 (52%) | 1.4 × 10⁻⁵ |
| | 168 ± 17 (30%) | 2.4 × 10⁻⁵ |
| | 759 ± 200 (18%) | 6.1 × 10⁻⁵ |
| | At +5.8 V | |
| Br (reverse bias) | 269 ± 58 (52%) | 1.6 × 10⁻⁵ |
| | 447 ± 49 (30%) | 2.3 × 10⁻⁵ |
| | 651 ± 110 (18%) | 4.1 × 10⁻⁵ |

The current density versus voltage, J(V), characteristics of PFBT-Br (FIG. 12b) exhibit a space charge limited current (SCLC) region, with a single discrete energy trap (J˜V² up to −2.55 V), followed by a transition to a trap filled region (J˜V⁸) in both the forward and reverse directions. PFBT-BAr^{F}₄ films also show two distinct regions: J˜V² up to −3.74 V, followed by a transition to J˜V⁶. It is possible to extract hole mobilities from the SCLC region (see Equation 2) and the results are contained in Table B. From these results, one finds that the intrinsic mobilities for forward bias of the various PFBT-Br locations (μ=1.4×10⁻⁵ to 6.1×10⁻⁵ cm²/V.s.) are higher than for PFBT-BAr^{F}₄ (μ=9.4×10⁻⁶ cm²/V.s.).

CAs also influence charge injection. The turn-on voltage for forward bias are −3.2 V (PFBT-Br) and −5 V (PFBT-BAr^{F}₄), The lower turn on voltage and the observable reverse bias current (charge injection from the ITO side) of the PFBT-Br film, relative to PFBT-BAr^{F}₄, may be due to the nature of the surface dipole or differences in HOMO levels and thus better energy alignment with ITO. Cyclic voltammetry measurements on PFBT-Br and PFBT-BAr^{F}₄ films show no change in the HOMO levels; this rules out the latter possibility. It is possible that the formation of the interfacial dipole by Br⁻ is more effective than BAr^{F}₄⁻, since the charge is more diffuse in the larger CA. Alternatively, local interactions with the electrode surface could be different for both CAs. We note that reducing the charge injection barrier in organic LEDs and thin film field effect transistors by interfacial dipoles is well documented. Despite these mechanistic uncertainties, the large impact on charge injection is unambiguously related to the CA, since both polymers contain the same backbone and thus similar HOMO levels.

In summary, a protocol is provided for exchanging CAs in conjugated polyelectrolytes, and is exemplified with PFBT. XPS provides straightforward characterization of CA content. Examination of the effect of CAs on the optical, charge transport, and aggregation properties of PFBT shows that the solid-state Φ values and the charge mobilities can be varied by close to an order of magnitude. Without wishing to be bound by theory, the most plausible explanation is that the size of the CA modulates the separation between chains, thereby reducing the extent of photoluminescence quenching. Consistent with this picture is that the absorption and emission spectra of PFBT-BAr^{F}₄ are less sensitive to different solvents, relative to PFBT-Br. Furthermore, the CA can also be used to control the apparent degree of aggregation in water, thereby providing a way to control interchain contacts in solution and ultimately in the bulk. The CAs are useful not only for modulating optical properties, but also for changing the charge mobility and charge injection barriers. More intimate chain contacts can also account for the increased mobility for PFBT-Br, relative to PFBT-BAr^{F}₄. Such improvements in emission output in the solid-state can expand the technological applications of conjugated polyelectrolytes, for example their use as the emissive layers in organic LEDs and the fabrication of more efficient single component LECs. For applications requiring high charge mobility such as ETL or HTL in LEDs, field effect transistors or photovoltaic devices, salts with smaller counterions such as PFBT-Br should prove more useful than those with larger counterions, such as PFBT-BAr^{F}₄.

### Example 16

### Conjugated Polyelectrolytes for Electron Injection Layers

Recent work has shown that it is possible to modulate the injection barriers at metal/organic semiconductor interfaces by changing the anion carried by cationic CPs. This is a fundamentally different observation than the changes in fluorescence quantum yield and charge mobility. Shown below is a straightforward method to exchange the counteranions of poly[(9,9-bis(6′-N;N;N-trimethylammonium)hexyl)fluorene]bromide (PF-Br). This polyfluorene homopolymer was synthesized by quaternization of pendant hexylbromide groups on the neutral precursor polymer using NMe₃, which yields fully quaternized PF with bromide CAs (PF-Br). Bromide exchange can be accomplished by dissolving the PF-Br in a methanol and water solution containing an excess of a salt with the CA of interest. The solvent is then removed under reduced pressure and the resulting solid is washed several times with deionized water. The analysis of PF-X (where X corresponds to the charge compensating anion, see Scheme C) films by X-ray photoelectron spectroscopy (XPS) confirms greater than 95% bromide exchanged.

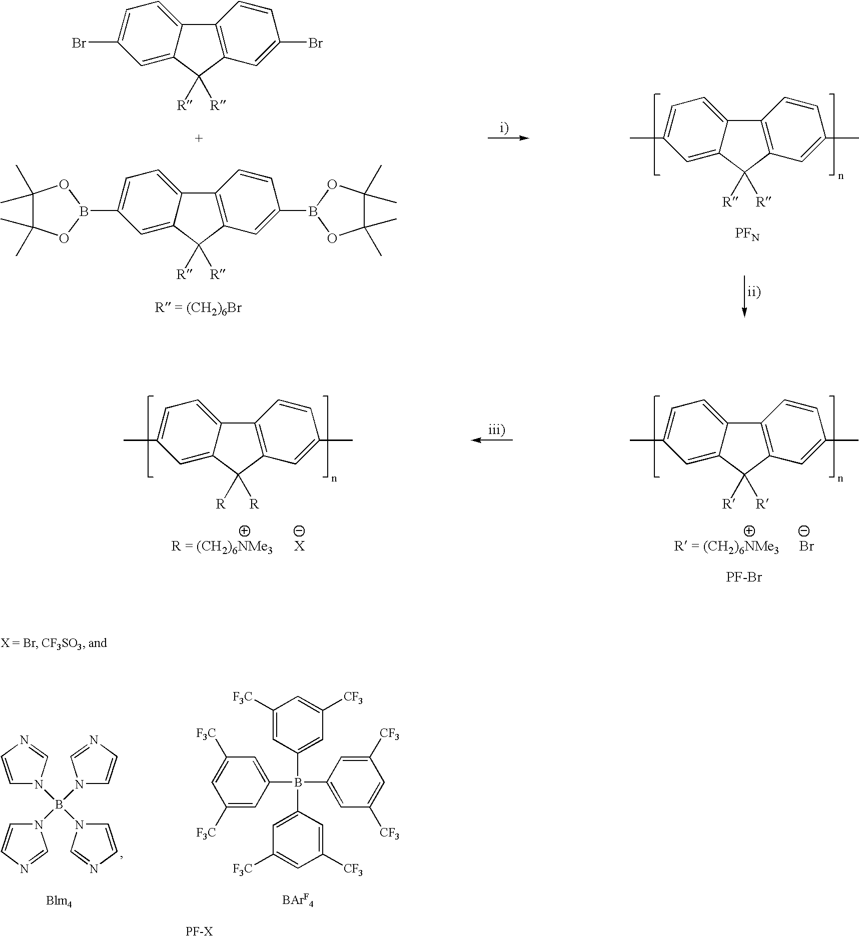

Scheme C. Synthesis of PF-X from PF-Br is shown above. Conditions: (i) Pd(PPh₃)₄, 2 M Na₂CO₃, toluene, reflux, 24 h; (ii) NMe₃; (iii) NaX, methanol.

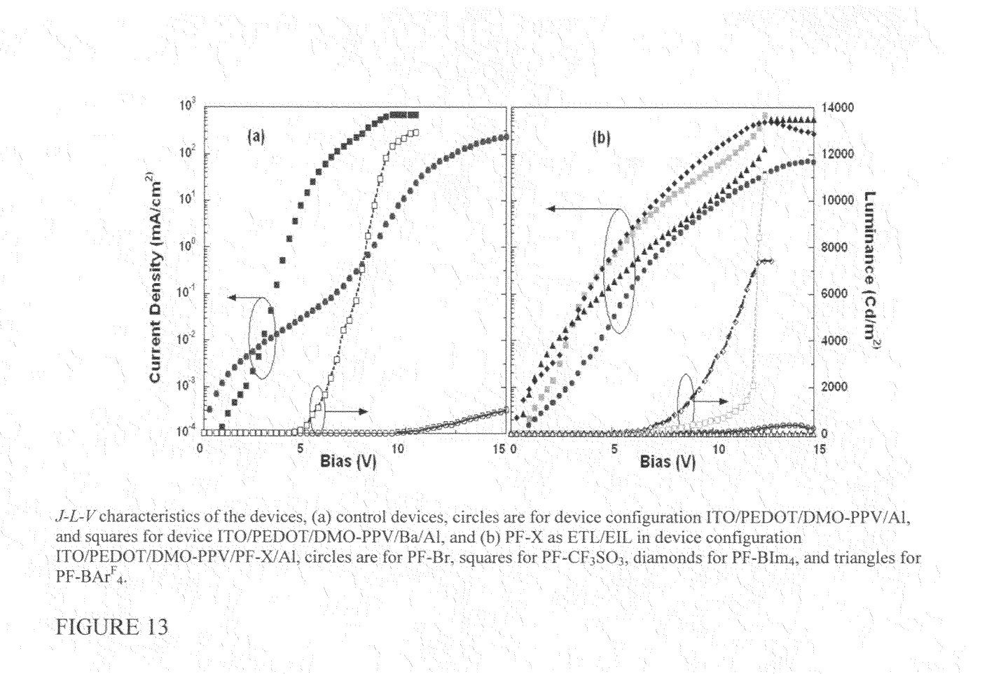

A very exciting discovery using PF-X with different counteranions is their use as the ETL/EIL in polymer LEDs. A summary of these findings are given in FIG. 13. In these experiments, we compare the current density-luminance-voltage (J-L-V) characteristics of different devices that have an emissive layer of poly[2-(4-3′,7′-dimethyloctyloxy)phenyl-p-phenylenevinylene] (DMO-PPV). FIG. 13a shows the characteristics of the control devices. When a high work function metal Al (4.2 eV) was directly deposited on DMO-PPV, the current increased slowly with applied voltage. The turn-on voltage was approximately 10 V, and the maximum brightness was close to 1000 Cd/m². Upon insertion of a thin layer of the low work function metal Ba (2.8 eV), the device performance increases remarkably, consistent with previous literature work. The turn-on voltage decreased to half of the former, and the luminance reached 13000 Cd/m² at operating voltage 10 V. The improvement resulted from the thin layer Ba lowering the barrier height, thus facilitating the electron injection and transport. FIG. 13b shows the effect of adding a 10 nm layer of PF-X materials on top of DMO-PPV, followed by Al deposition. For PF-Br, the J-L-V curves were similar to that of DMO-PPV/Al device, and for PF-BAr^{F}₄, they became worse. However, insertion of PF-CF₃S0₃ or PF-BIm₄ as the ETL/EIL give rise to J-L-V characteristics that are close to those of DMO-PPV/Ba/AI devices. The current increases quickly, the turn-on voltages are as low as 5 V, and the luminance reached more than 7000 and 11000 Cd/m² for PF-BIm₄ and PF-CF₃S0₃, respectively.

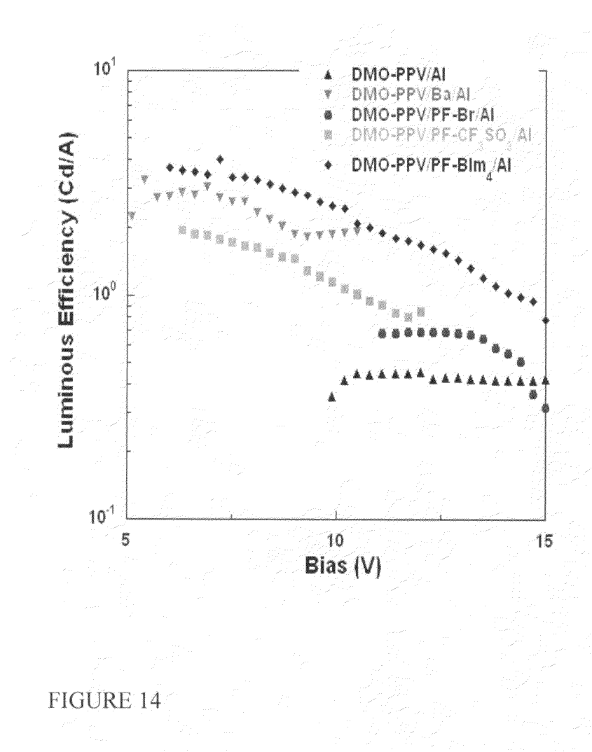

The luminous efficiencies of PF-X containing LEDs are consistent with the J-L-V curves (FIG. 14). The efficiencies of devices fabricated with PF-BIm₄ or PF-CF₃S0₃ as ETL/EIL are comparable to those of Ba devices, or even slightly higher. However, for PF-Br, efficiency is close to that of DMO-PPV/Al device and for PF-BAr^{F}₄, the device function is negligible.

Although the invention has been described in some detail with reference to the preferred embodiments, those of skill in the art will realize, in light of the teachings herein, that certain changes and modifications can be made without departing from the spirit and scope of the invention. Accordingly, the invention is limited only by the claims.

### REFERENCES

The following publications are hereby incorporated by reference.
1. Cimrova et al. Adv. Mat. 1996, 8, pages 585-588.
2. Thunemann et al. Langmuir 2001, 17, pages 5098-5102.
3. Baur et al. Adv. Mat. 1998, 10, pages 1452-1455.
4. U.S. Pat. No. 6,083,635 to Jonas
5. Morin et al., Chem. Mater. 2004, vol. 16, No. 23, pages 4619-4626.
6. N. S. Cho et al. Macromolecules, Vol. 37, No. 14, pages 5265-5273.
7. Ajayaghosh, A., et al., Chem. Soc. Rev., 2003, 32, 181.
8. A. Ajayagosh and J. Eldo, Organic Letters, 2001, 3, 2595-2598.
9. D. Nakamura et al. Nature 430, 1009, 2004.
10. D. Moses, Appl. Phys. Lett. 60, 3215 (1992);
11. U.S. Pat. No. 5,237,582.
12. F. Hide, M. A. Diaz-Garcia, B. J. Schwartz, M. R. Andersson, Q. Pei, and A. J. Heeger, Science 273, 1833 (1996).
13. N. Tessler, G. J. Denton, and R. H. Friend, Nature 382, 695 (1996).
14. U.S. Pat. No. 5,881,083 issued Mar. 9, 1999 to Diaz-Garcia et al. and titled “Conjugated Polymers as Materials for Solid State Lasers.”
15. X. Gong et al., Adv. Func. Mater., 2004, 14, 393.
16. J. C. Ostrowski, M. R. Robinson, A. J. Heeger and G. C. Bazan, Chem. Commun., 2002, 7, 784.
17. X. Gong, D. Moses and A. J. Heeger, Synth. Met. 2004, 141, 17.
18. X. Gong, J. C. Ostrowski, D. Moses, G. C. Bazan, A. J. Heeger, M. S. Liu, A. K-Y. Jen, Adv. Mat. 2003, 15, 45.
19. X. Gong, J. C. Ostrowski, D. Moses, G. C. Bazan, A. J. Heeger, J. Poly. Sci. Poly. Phys., 2003, 41, 2691.
20. T. J. Boyd, R. R. Schrock, Macromolecules, 1999, 32, 6608.
21. So Wang, Z. Zeng, S. Yang, L.-T. Weng, P. C. L. Wong, K. Ho, Macromolecules, 2000, 33, 3232.
22. S. Liu, X. Z. Jiang, H. Ma, M. S. Liu, A. K.-Y. Jen, Macromolecules, 2000, 33, 3514.
23. X. Gong, D. Moses, A. J. Heeger, S. Liu and A. K.-Y. Jen, Appl. Phys. Lett., 2003, 83, 183.

1. A formulation comprising a salt, the salt comprising:
a polyionic conjugated polymer comprising a plurality of first charges;
and a plurality of counterions, each of said plurality comprising a charged moiety electronically linked to at least one charge-distributing moiety, said charged moiety having a charge opposite in sign to that of the first charge.

2. The formulation of claim 1, wherein the first charges are positive charges.

3. The formulation of claim 1, wherein the first charges are negative charges.

4. The formulation of claim 1, wherein the charge-distributing moiety comprises an electron-donating group or an electron-withdrawing group.

5. The formulation of claim 1, wherein the electron-withdrawing group is selected from a group consisting of a halogen and a haloalkyl group.

6. The formulation of claim 1, wherein the charge-distributing moiety comprises an optionally substituted aromatic ring.

7. The formulation of claim 1, wherein the charged moiety is selected from a group consisting of negatively charged boron, sulfate, sulfonate, phosphate, phosphonate, carboxylate, and nitrate.

8. The formulation of claim 1, wherein the counterions comprise aryl borates.

9. The formulation of claim 1, wherein the salt is selected from the group consisting of Poly[(9,9-bis(6′-N,N,N-trimethylammonium)hexyl)fluorene-alt-4,7-(2,1,3-benzothiadiazole)]tetrafluoroborate (PFBT-BF₄), Poly[(9,9-bis(6′-N,N,N-trimethylammonium)hexyl)fluorene-alt-4,7-(2,1,3-benzothiadiazole)]hexafluorophosphate (PFBT-PF₆), Poly[(9,9-bis(6′-N,N,N-trimethylammonium)hexyl)fluorene-alt-4,7-(2,1,3-benzothiadiazole)]trifluoromethanesulfonate (PFBT-CF₃S0₃), Poly[(9,9-bis(6′-N,N,N-trimethylammonium)hexyl)fluorene-alt-4,7-(2,1,3-benzothiadiazole)]tetraphenylborate (PFBT-BPh₄), Poly[(9,9-bis(6′-N,N,N-trimethylammonium)hexyl)fluorene-alt-4,7-(2,1,3-benzothiadiazole)]tetrakis(1-imidazolyl)borate (PFBT-BIm₄), Poly[(9,9-bis(6′-N,N,N-trimethylammonium)hexyl)fluorene-alt-4,7-(2,1,3-benzothiadiazole)]tetrakis(2-thienyl)borate (PFBT-BTh₄), Poly[(9,9-bis(6′-N,N,N-trimethylammonium)hexyl)fluorene-alt-4,7-(2,1,3-benzothiadiazole)]tetrakis[3,5-bis(trifluoromethyl)phenyl]borate (PFBT-BAr^{F}₄), Poly[(9,9-bis(6′-N,N,N-trimethylammonium)hexyl)fluorene]trifluoromethanesulfonate (PF-CF₃S0₃), Poly[(9,9-bis(6′-N,N,N-trimethylammonium)hexyl)fluorene]tetrakis(1-imidazolyl)borate (PF-BIm₄), Poly[(9,9-bis(6′-N,N,N-trimethylammonium)hexyl)fluorene]tetrakis[3,5-bis(trifluoromethyl)phenyl]borate (PF-BAr^{F}₄), Poly[(9,9-bis(6′-N,N,N-trimethylammonium)hexyl)fluorene-alt-1,4-phenyl)]tetrakis(pentafluorophenyl)borate (PFB-BPh^{F}₄), and Poly[(9,9-bis(6′-N,N,N-trimethylammonium)hexyl)fluorene-alt-4,4-((N-4′-(6″-N,N,N-trimethylammonium)hexyl)phenyl)diphenylamine]trifluoromethanesulfonate (PFTPA-CF₃S0₃).

10. The formulation of claim 1, wherein each of said plurality of counterions comprises at least 7 atoms over which the charge is distributed.

11. The formulation of claim 1, wherein the conjugated polymer is a copolymer.

12. The formulation of claim 1, wherein the conjugated polymer is selected from optionally substituted polyfluorene, optionally substituted poly(fluorene-alt-benzothiadiazole), and optionally substituted poly(fluorene phenylene), and optionally substituted poly(fluorene triphenylamine).

13. The formulation of claim 1, wherein the counterions are effective to reduce aggregation of the polyionic polymer as measured by at least one of: blue-shift of photoluminescent emission under at least one set of conditions; spectral width is narrowed; increased photoluminescent efficiency; reduced apparent size; and viscosity.

14. The formulation of claim 1, wherein the salt is purified.

15. The formulation of claim 1, further comprising a solvent.

16. The formulation of claim 15, wherein the solvent is selected from a group consisting of dimethylsulfoxide, dimethylformamide and methanol.

17. A film comprising the formulation of claim 1.

18. The film of claim 17, wherein the film has a thickness of less than 200 nm.

19. A substrate comprising the formulation of claim 1.

20. A method of improving the uniformity of a deposited layer of the formulation of claim 1, comprising stirring a methanolic solution comprising said salt for at least 4 hours prior to deposition.

21. A device comprising the formulation of claim 1.

22. The device of claim 21, wherein the device is selected from the group consisting of an optical component, an electrical component, an optoelectronic device, a biosensor, a photodiode, a light-emitting diode (LED), an optoelectronic semiconductor chip, a semiconductor thin-film, a field-effect transistor (FET), a polymeric photoswitch, an optical interconnect, a transducer, a lasing material, a light-emitting electrochemical cell (LEe), a solar cell, a photovoltaic, and a liquid crystal.

23. The LED device of claim 22, further comprising an electron transport layer comprising a formulation according to claim 1.

24. The LED of claim 22, wherein the LED exhibits one or more properties selected from the group consisting of increased luminance, altered onset voltage, and altered charge mobility, as compared to an LED not comprising said counterion.

25. The LED of claim 22, wherein the counterions increase the ability of the conjugated polymer to inject and/or transport electrons.

26. The LED of claim 22, wherein the salt blocks the electrical transport of holes.

27. An inkjet cartridge comprising the formulation of claim 15.

28. A matrix comprising a plurality of LEDs according to the device of claim 22.

29. A display device comprising the LED of claim 22.

30. A method for the production and characterization of a solar cell, photovoltaic, and field-effect transistor, comprising providing a conjugated polyelectrolyte, and performing ion exchange on said conjugated polyelectrolyte.

31. The method according to claim 30, wherein the ion exchange alters the charge mobility, charge collection, and/or open circuit voltage of the solar cell or photovoltaic.

32. The method according to claim 30, wherein the ion exchange alters the charge mobility or charge injection of the field-effect transistor.
